(19) United States
(12) Patent Application Publication
(10) Pub. No.: US 2026/0009842 A1
(43) Pub. Date: Jan. 8, 2026

(54) INTEGRATED HEATER AND COLD PLATE FOR TEST APPLICATIONS

(71) Applicant: AEM Singapore Pte. Ltd., Singapore (SG)

(72) Inventors: Samer KABBANI, Laguna Niguel, CA (US); Thomas P. JONES, Stanwood, MI (US); Sorin DINESCU, Temecula, CA (US)

(21) Appl. No.: 18/766,419

(22) Filed: Jul. 8, 2024

(51) Int. Cl. G01R 31/28; H01L 21/66; H01L 23/34; H01L 23/467

(52) U.S. Cl. CPC G01R 31/2875; G01R 31/2877; H01L 22/12; H01L 23/345; H01L 23/467

(57) ABSTRACT

A thermal control system comprising an integrated heater and cold plate is disclosed. The integrated heater and cold plate comprises a heat transfer geometry for transferring heat from the heater to the cold plate. The heat transfer geometry may comprise a plurality of fins configurable for changing the heat transfer rate between the heater and the cold plate. For example, the number of fins, spacing between fins, size of the base of the cold plate, fluid flow through the fins, etc. may be configured to increase or decrease the heat transfer rate. In some examples, the heat transfer geometry may be deposited directly on or permanently attached to the base of the cold plate or heater. In some examples, the heater may directly contact the heat transfer geometry. The thermal control system may not include air or a thermal interface material (TIM) between the heater and the heat transfer geometry.

### FIELD

The present disclosure relates to a thermal control system with an integrated heater and cold plate used to attain or maintain a setpoint temperature for devices or components undergoing electrical testing.

### BACKGROUND

Integrated circuit (IC) chips are tested to ensure that their performances meet certain performance criteria. It may be desirable to test the IC chips as early as possible in the manufacturing process so that any IC chips that do not meet the performance criteria are removed from the process before further expensive processing steps are applied. The process for manufacturing chips may comprise manufacturing semiconductor IC devices, transistors, diodes, passive components, micro-electromechanical systems (MEMS), or other types of devices on a semiconductor wafer, and interconnecting those devices on the wafer to form circuits, sensors, or other functional units. The circuits, sensors, or other functional units are combined to provide desired functions within a physical outline on the wafer referred to as a chip. There may be tens or thousands of chips on an individual wafer depending on the wafer size and/or the chip size. The electrical testing of individual IC chips while still part of a semiconductor wafer may be referred to as “wafer probe” testing. A wafer probe test is used to determine which IC chips are defective and which are considered good due to passing the wafer probe test. The wafer probe test involves using a wafer probe interface that comprises contacts such as needles or probe pins that are configured to temporarily electrically couple with electrical pads formed on the IC chip during a test sequence. The electrical pads are formed while the IC chip is part of the semiconductor wafer. One or more signals, such as power and input/output signals, are applied by the wafer probe interface to the electrical pads of the IC chips.

After the wafer probe test, the semiconductor wafer is cut into individual (also referred to as “singulated”) IC chips, which are then assembled into packages to result in packaged IC chips. It may be noted that packages may not be limited to housing just one chip but may comprise multiple chips, as well as other components (such as discrete passive devices, integrated passive devices, bridge or interposers, or other components). The packaged IC chips may be subject to one or more other electrical tests, such as package-level testing that may include burn-in testing or functional testing. In some examples, package-level testing may be the final test performed while a package is in a stand-alone packaged state (not assembled onto a printed circuit board). After the final (package-level) test, the packages may be soldered onto printed circuit boards (PCBs), and the PCBs are then assembled together in a system. Once packages are assembled onto PCBs or PCBs are assembled to form a system, further electrical testing may be performed.

A device under test (DUT) may be a device subject to an electrical test. Depending on the context, the term DUT can refer to different types of devices. In the context of a wafer probe test, a DUT may be a chip, or a group of chips electrically coupled by a probe interface at a given time to enable electrical testing. For a package undergoing electrical testing, the package is the DUT. For a PCB undergoing electrical testing, the PCB is the DUT. For a system undergoing electrical testing, the system is the DUT.

Electrical testing, regardless of the type (e.g., wafer probe, package-level, PCB-level, or system-level) can be very sophisticated, using technologically advanced testers, where the amount of time for testing can be greater than tens of seconds per DUT. Advanced testers may cost several million dollars each. For electrical testing, the DUTs may be tested at different setpoint temperatures, where it is desirable that the temperatures of the DUTs are accurate and stable while the testing is performed. A thermal controller determines the temperature of the (DUT) and/or the temperature of a thermal control element that is in close proximity to the DUT. In some instances, a tester may determine the temperature of the DUT (e.g., using an on-chip temperature sensor) and send it to the thermal controller. If the determined temperature is outside of a desired range around a setpoint temperature, then the thermal controller may attempt to heat or cool the DUT or thermal control element. The thermal controller waits until the DUT temperature and/or thermal control clement temperature is within the desired range or stops testing. Since the test system can be very expensive, the time that a test system sits idle waiting (e.g., not performing a test) can lead to significant amounts of money lost.

For electrical testing, heating or cooling a DUT may comprise using a thermal mass (e.g., heated and/or cooled element) that the DUT thermally couples to during testing. For example, before wafer probe testing, a semiconductor wafer may be placed on a chuck that includes thermal control elements. The wafer probe test system changes the temperature of the thermal control elements to a setpoint temperature or maintains it, which then affects the temperature of the semiconductor wafer. However, the thermal control elements may not adequately respond to localized temperature changes that occur due to, e.g., individual high-performance IC chips being tested when operating with their targeted performance, limiting the wafer probe testing of certain IC chips. Furthermore, the wafer probe test system or thermal control elements, due to, e.g., their large thermal mass, may not be able to quickly transition from one setpoint temperature to another. Any delay in transitioning from one temperature to another is costly since the tester is idle and not utilized during the temperature transition. In some instances, when a high-powered IC chip is being tested, the thermal control elements may not be able to change temperatures fast enough to keep the IC chip within an acceptable temperature range. In some instances, the temperature of the IC chip may become too high, damaging the chip. While this discussion has described potential issues with wafer probe testing, similar issues may arise at any level of electrical testing (wafer, package, PCB, system level, etc.).

Chip power, including the power density (the power of a chip divided by its surface area), has been increasing for some chips. It may be desirable to have a thermal control system capable of heating or cooling areas or zones with a power density corresponding to the power density of a chip or multiple chips that form a DUT.

One non-limiting problem to creating an efficient and high-performance thermal control system is that heating elements such as heaters, cooling elements such as cold plates or heatsinks, and other system elements (such as adapters or chucks) may be discrete elements that are assembled together. The surfaces of discrete elements (such as the surface of a heater) at the microscopic scale are not perfectly flat or uniform and may contain ridges, asperities, or other non-uniformities, which may reduce thermal coupling. When multiple discrete elements are assembled together, e.g., such that their imperfect surfaces are adjacent to each other, there are gaps (e.g., air) between the surfaces that increase the thermal resistance between the discrete elements. In other words, it may be difficult to transfer heat from one discrete element to another due to the gaps formed between adjacent surfaces having reduced thermal coupling.

To mitigate the issue of high thermal resistance between discrete elements assembled together, a material, which may be referred to as a thermal interface material (TIM), may be introduced between the discrete elements to help fill in the gaps between their imperfect surfaces. The TIM may be a paste, gel, grease, water, a low melting point metal, or other material. Although a TIM may help to reduce the thermal resistance between two discrete elements, the thermal resistance between discrete elements in a thermal control system may comprise a large amount (e.g., a significant amount including a majority portion) of the overall thermal resistance of the system.

If discrete elements in a thermal control system can be integrated together as a single component, then the thermal resistance between the two discrete elements may reduced (e.g., zero or close to zero), reducing the overall thermal resistance of the thermal control system. Keeping the thermal resistance of the thermal control system as low as possible affects the thermal control system in many ways, such as allowing the thermal control system to transition from one setpoint temperature to another setpoint temperature as quickly as possible, minimizing the overall power required, allowing higher setpoint temperatures to be achieved, and/or minimizing the overall size or cost of the thermal control system.

Thermal control systems and methods that adequately respond to localized temperature changes, transition quickly from one setpoint temperature to another, can provide a high-power density, have lower thermal resistance, and/or reduce overall size or costs are desired.

### SUMMARY

Disclosed herein are thermal control systems and methods for forming and operation thereof. A thermal control system may comprise an integrated heater and cold plate is disclosed. The integrated heater and cold plate comprises a heat transfer geometry for transferring heat from the heater to the cold plate. The heat transfer geometry may comprise a plurality of fins configurable for changing the heat transfer rate between the heater and the cold plate. For example, the number of fins, spacing between fins, size of the base of the cold plate, fluid flow through the fins, etc. may be configured to increase or decrease the heat transfer rate. In some examples, the heat transfer geometry may be deposited directly on or permanently attached to the base of the cold plate or heater. In some examples, the heater may directly contact the heat transfer geometry. The thermal control system may not include air or a thermal interface material (TIM) between the heater and the heat transfer geometry.

A thermal control system for controlling a temperature of one or more zones of a device under test (DUT), the thermal control system comprising: an integrated heater and cold plate comprising: a heater; a base; and a heat transfer geometry deposited directly on or permanently attached to the base or the heater. Additionally or alternatively, in some embodiments, the heater directly contacts the heat transfer geometry. Additionally or alternatively, in some embodiments, the thermal control system excludes air or a thermal interface material (TIM) between the heater and the heat transfer geometry. Additionally or alternatively, in some embodiments, the heater is joined to the base. Additionally or alternatively, in some embodiments, the base is a substrate of the heater. Additionally or alternatively, in some embodiments, the base comprises a ceramic dielectric material. Additionally or alternatively, in some embodiments, the base comprises one or more metallization layers. Additionally or alternatively, in some embodiments, the one or more metallization layers comprise: an adhesion/barrier layer comprising titanium (Ti), chrome (Cr), tungsten (W), tantalum (Ta), titanium nitride (TiN), tantalum nitride (TaN), or a combination thereof; or a seed layer comprising copper (Cu), aluminum (Al), gold (Au), nickel (Ni), or a combination thereof. Additionally or alternatively, in some embodiments, the heat transfer geometry and base are included in a cold plate. Additionally or alternatively, in some embodiments, the heat transfer geometry is at least partially formed using a physical vapor deposition process, a plating process, an additive manufacturing process, or a combination thereof. Additionally or alternatively, in some embodiments, the heat transfer geometry comprises one or more rectangular fins, pin fins, or gyroid fins. Additionally or alternatively, in some embodiments, the heater comprises a plurality of heating zones, wherein the heat transfer geometry is thermally coupled to multiple of the plurality of heating zones. Additionally or alternatively, in some embodiments, the heater comprises at least one heating zone, wherein the heat transfer geometry is thermally coupled to the at least one heating zone. Additionally or alternatively, in some embodiments, the heater is attached to the base through brazing, soldering, transient liquid phase bonding, sintering, adhesive bonding, or another permanent bonding process. Additionally or alternatively, in some embodiments, further comprising: threaded studs or mechanical support structures affixed to the heater by brazing, soldering, transient liquid phase bonding, sintering, adhesive bonding, or another permanent bonding process. Additionally or alternatively, in some embodiments, the heater comprises dielectric layers and conductive layers. Additionally or alternatively, in some embodiments, the dielectric layers comprise aluminum nitride (AlN). Additionally or alternatively, in some embodiments, the heater comprises a plurality of independently controlled heating zones. Additionally or alternatively, in some embodiments, the heater is coupled to a thermal controller, wherein the thermal controller controls the heater by controlling an electrical power supplied to the heater. Additionally or alternatively, in some embodiments, the heater is capable of being independently controlled separately from the cold plate. Additionally or alternatively, in some embodiments, the heater and cold plate are controlled by a thermal controller. Additionally or alternatively, in some embodiments, the heater is controlled by a first thermal controller, and the cold plate is controlled by a second thermal controller. Additionally or alternatively, in some embodiments, the cold plate comprises a plurality of independently controlled cooling zones. Additionally or alternatively, in some embodiments, the cold plate is controlled by a thermal controller, wherein the thermal controller controls a coolant fluid flowing through the cold plate. Additionally or alternatively, in some embodiments, the heater is configured to support a thermal interface material (TIM). Additionally or alternatively, in some embodiments, wherein the TIM comprises a liquid TIM or a gas TIM. Additionally or alternatively, in some embodiments, wherein the gas TIM includes helium.

It will be appreciated that any of the variations, aspects, features, and options described in view of the systems and methods apply equally to the methods and vice versa. It will also be clear that any one or more of the above variations, aspects, features, and options can be combined. It should be understood that the invention is not limited to the purposes mentioned above, but may also include other purposes, including those that can be recognized by one of ordinary skill in the art.

### BRIEF DESCRIPTION OF THE FIGURES

FIG. 1A illustrates a side view of an example system, including a thermal control system, for electrical testing, according to some embodiments.

FIG. 1B illustrates a schematic diagram of an example electrical test system and thermal control system, according to some embodiments.

FIG. 2A illustrates a side view of a portion of an example thermal control system, according to some embodiments.

FIG. 2B illustrates an example integrated heater and cold plate, according to some embodiments.

FIG. 3A illustrates an example configuration for a portion of a cold plate, according to some embodiments.

FIG. 3B illustrates an example heat transfer geometry comprising pin fins arranged on a base, according to some embodiments.

FIG. 3C illustrates an example heat transfer geometry comprising gyroid fins, according to some embodiments.

FIG. 3D illustrates a close-up view of an example unit cell of gyroid fins, according to some embodiments.

FIG. 3E illustrates an example heat transfer geometry comprising gyroid fins having a plurality of geometries, according to some embodiments.

FIG. 3F illustrates an example heat transfer geometry joined to a heater, according to some embodiments.

FIG. 4A illustrates an example heater comprising a dielectric material, according to some embodiments.

FIG. 4B illustrates an example metallization layer, according to some embodiments.

FIG. 4C illustrates example fins that have been electroplated on a metallization layer, according to some embodiments.

FIG. 4D illustrates example connector pins attached to the pads on a heater, according to some embodiments.

FIG. 4E illustrates an example heater after the metallization layer has been etched away, according to some embodiments.

FIG. 4F illustrates an example heat transfer geometry, according to some embodiments.

FIG. 5A illustrates an integrated heater and cold plate, according to some embodiments.

FIG. 5B illustrates a top-down view of an example integrated heater and cold plate, according to some embodiments.

FIG. 5C illustrates a section view of an example integrated heater and cold plate, according to some embodiments.

FIG. 5D illustrates examples of additional components added to an example integrated heater and cold plate, according to some embodiments.

FIG. 5E illustrates a top-down view of an example integrated heater and cold plate, according to some embodiments.

FIG. 5F illustrates a section view of an example integrated heater and cold plate, according to some embodiments.

FIG. 6A illustrates an example heat transfer geometry formed on a heater, according to some embodiments.

FIG. 6B illustrates an example integrated heater and cold plate with a first cover of a cover structure, according to some embodiments.

FIG. 6C illustrates an example integrated heater and cold plate with a second cover of a cover structure, according to some embodiments.

FIG. 6D illustrates a perspective view of the bottom of an example first cover of a cover structure, according to some embodiments.

FIG. 6E illustrates a top-down, plan view of an example integrated heater and cold plate, according to some embodiments.

FIG. 6F illustrates a section view of an example integrated heater and cold plate, according to some embodiments.

FIG. 7A illustrates an example thermoelectric cooler (TEC) that has been incorporated between the heater and the cold plate, according to some embodiments.

FIG. 7B illustrates an example TEC that attaches directly to the cold plate (or an adapter coupled to the cold plate), according to some embodiments.

FIG. 8A illustrates an example thermal control component comprising different sized heaters, according to some embodiments.

FIG. 8B illustrates a section view an example thermal control component, according to some embodiments.

FIG. 9A illustrates examples of integrated heaters and cold plates, according to some embodiments.

FIG. 9B illustrates a section through an example thermal control assembly, according to some embodiments.

FIG. 9C illustrates an example thermal control assembly, according to some embodiments.

FIG. 9D illustrates an example thermal control assembly configured for testing an undiced or diced semiconductor wafer DUT, according to some embodiments.

FIG. 9E illustrates an example heater with associated integrated heat transfer geometry before it is assembled to the cover structure, according to some embodiments.

FIG. 9F illustrates an example thermal control assembly comprising heaters comprising a plurality of different heating zones, according to some embodiments.

FIG. 9G illustrates an example thermal control assembly that includes a heater comprising a plurality of heating zones, according to some embodiments.

FIG. 9H illustrates an example heater with integrated heat transfer geometry that is thermally coupled to heating zones being assembled into cover structure of the thermal control assembly, according to some embodiments.

FIG. 9I illustrates an example heater with associated integrated heat transfer geometry before it is assembled to the cover structure, according to some embodiments.

FIG. 9J illustrates an example heater with integrated heat transfer geometry that is thermally coupled to heating zones being assembled into cover structure of the thermal control assembly, according to some embodiments.

FIG. 10 illustrates an example heater configured to support a liquid thermal interface material (LTIM), according to some embodiments.

FIG. 11 illustrates an example diagram of an LTIM system, according to some embodiments.

FIG. 12A illustrates an example thermal control assembly divided into heating zones, according to some embodiments.

FIGS. 12B and 12C illustrate side views through a heating zone of an example thermal control assembly that includes a cover structure, according to some embodiments.

FIG. 12D illustrates a top plan view of a portion of an example thermal control assembly including a cavity, but without a heater installed, according to some embodiments.

FIG. 13 illustrates an example temperature control system for a thermal control assembly, according to some embodiments.

It will be appreciated that any of the variations, aspects, features, and options

described in view of the systems apply equally to the methods and vice versa. It will also be clear that any one or more of the above variations, aspects, features, and options can be combined.

### DETAILED DESCRIPTION

The following description is presented to enable a person of ordinary skill in the art to make and use various embodiments. Descriptions of specific devices, techniques, and applications are provided only as examples. These examples are being provided solely to add context and aid in the understanding of the described examples. It will thus be apparent to a person of ordinary skill in the art that the described examples may be practiced without some or all of the specific details. Other applications are possible, such that the following examples should not be taken as limiting. Various modifications in the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

Various techniques and process flow steps will be described in detail with reference to examples as illustrated in the accompanying drawings. In the following description, numerous specific details are set forth in order to provide a thorough understanding of one or more aspects and/or features described or referenced herein. It will be apparent, however, to a person of ordinary skill in the art, that one or more aspects and/or features described or referenced herein may be practiced without some or all of these specific details. In other instances, well-known process steps and/or structures have not been described in detail in order to not obscure some of the aspects and/or features described or referenced herein.

In the following description of examples, reference is made to the accompanying drawings which form a part hereof, and in which it is shown by way of illustration specific examples that can be practiced. It is to be understood that other examples can be used, and structural changes can be made without departing from the scope of the disclosed examples.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. It will also be understood that the term “same,” when used in this specification, refers to the stated feature as being identical or within a certain range (e.g., 1%, 5%, etc.) from identical.

Although the disclosure herein is discussed specifically in the context of electrical testing, aspects of the disclosure apply to other applications including, but not limited to, semiconductor fabrication operations, IC package assembly, food or chemical processing, biological or biochemical applications, or other types of applications.

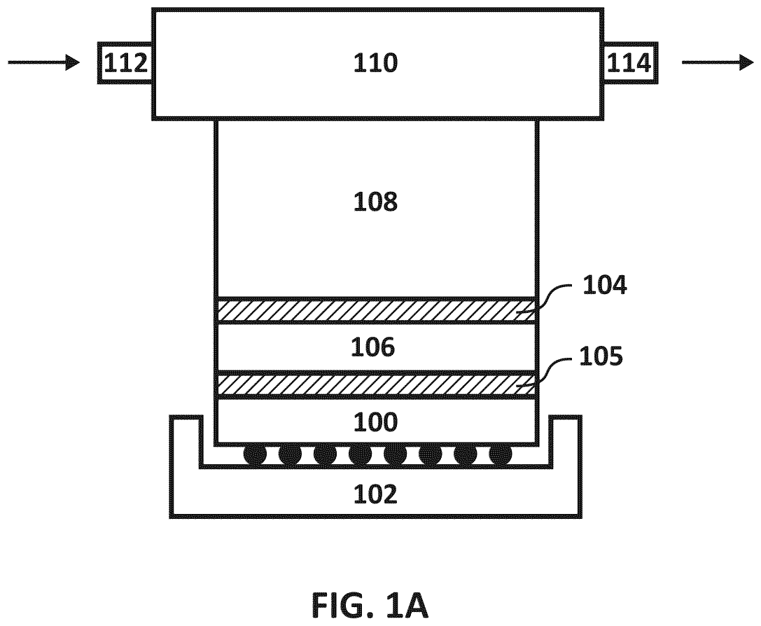

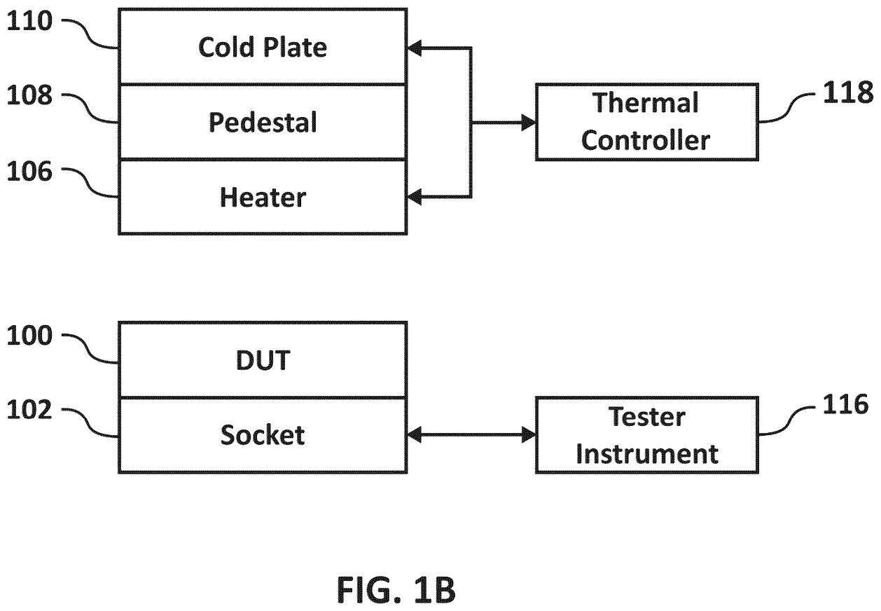

FIG. 1A depicts a side view of a system, including a thermal control system, for electrical testing, according to some embodiments. In some instances, the system may be used for package-level testing, where the DUT is a package. A DUT 100 is seated in a socket 102 so that electrical connections can be made from the DUT 100 through the socket 102 to a tester (not shown). To control the temperature of the DUT 100 during testing, the system may comprise a thermal control system. The thermal control system comprises a heater 106 and a cold plate 110. An adapter 108 (also referred to as pedestal 108) may extend from the cold plate 110. The cold plate 110 may be cooled by a cold fluid that enters an inlet 112 to the cold plate 110 and exits via an outlet 114 from the cold plate 110. The cold plate 110 and/or adapter 108 may be an independent part that is assembled with the heater 106. The heater 106 may also be an independent part. To reduce thermal resistance between the cold plate 110 and heater 106, a first TIM 104 is placed between the cold plate 110 (or its adapter 108) and the heater 106. A second TIM 105 may also be used between the heater 106 and the DUT 100. One or more TIMs 104 and 105 shown in FIG. 1A are optional. In some examples, TIM 104 may comprise a material different than TIM 105.

FIG. 1B illustrates a schematic diagram of the electrical test system and thermal control system shown in FIG. 1A, according to some embodiments. As previously described, the DUT 100 interfaces with socket 102. As shown in FIG. 1B, the socket 102 couples with a loadboard or tester instrument 116 that further couples with a tester (not shown). With respect to a portion of the thermal control system, FIG. 1B shows a cold plate 110 comprising a pedestal 108 which may be in contact with a heater 106. The cold plate 110 and heater 106 may be coupled with a thermal controller 118. The thermal controller 118 may determine the temperature of one or more elements within the thermal control system (such as the temperature of the cold plate 110, the temperature of the heater 106, etc.). The thermal controller 118 optionally accepts other inputs (such as the internal temperature of the DUT, e.g., determined by a temperature-measuring device within a chip, or the DUT power). Based on the temperatures and other inputs, the thermal controller 118 may calculate a DUT temperature. If the DUT temperature deviates more than an acceptable amount from a setpoint temperature for the DUT, the thermal controller 118 may make adjustments to elements within the thermal control system, such as heaters 106 or cold plates 110, to raise or lower their temperature, thereby adjusting or maintaining the DUT temperature to be within an acceptable range of the setpoint temperature for the DUT.

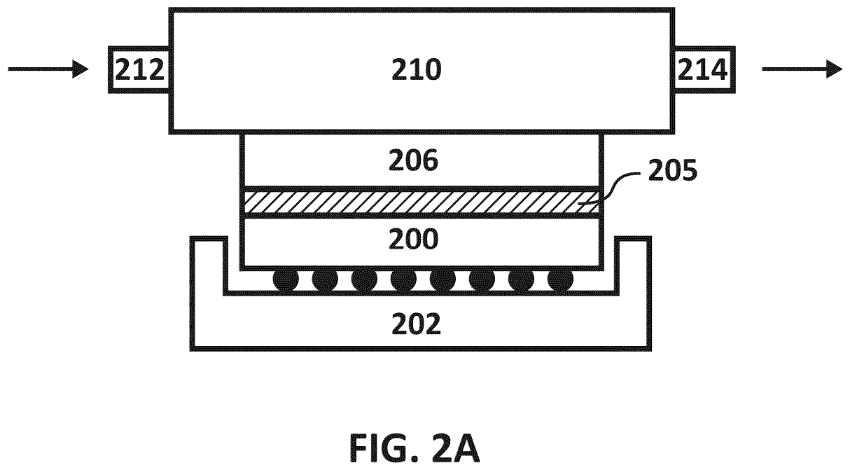

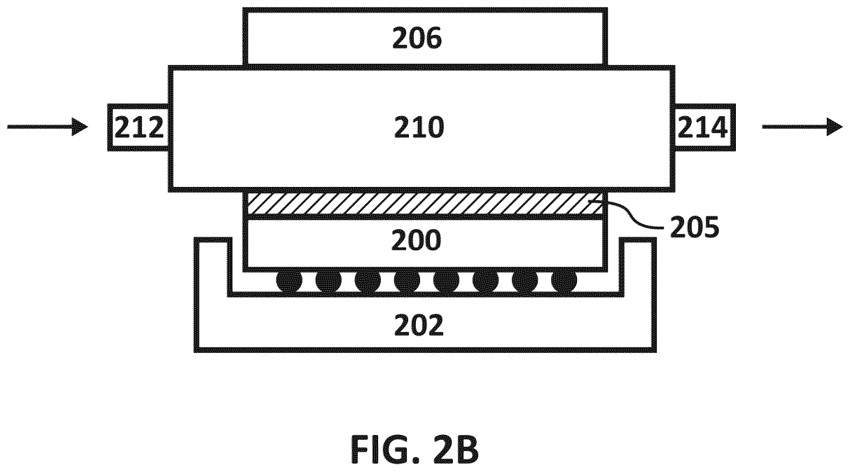

FIG. 2A illustrates a side view of a portion of an example thermal control system, according to some embodiments. The thermal control system may comprise a cold plate 210 that is integrated with the heater 206. Cold plate 210 includes a fluid inlet 212 and a fluid outlet 214. A socket or contactor 202 makes electrical contact with the DUT 200. In some examples, the cold plate 210 may be integrated with the heater 206, where active cooling elements of the cold plate 210 (such as cooling fins and fluid channels) are directly attached to or deposited on the heater 206. In some examples, the thermal control may exclude an assembly comprising multiple (e.g., two) independent parts (e.g., a heater 106 and a cold plate 110 as shown in FIG. 1A). There may be a single, integrated part that comprises the heater 206 and the active cooling elements of the cold plate 210, for example. In some examples, the heater 206 and cold plate 210 are integrated in the thermal control system of FIG. 2A. The thermal control system may not include a first TIM between the heater 206 and the cold plate 210.

FIG. 2A shows an optional TIM 205 between the DUT 200 and the heater 206. Although FIG. 2A depicts heater 206 being adjacent to the DUT 200, in some cases, the cold plate 210 may be located closer to the DUT 200, while both heater 206 and cold plate 210 form an integrated part as shown in FIG. 2B. Although not shown in FIGS. 2A or 2B, an adapter could be incorporated into the integrated heater 206 and/or cold plate 210, like the adapter 108 of FIG. 1A.

A cold plate 210 or heatsink may transfer heat from some of its warmer surfaces to a cooling fluid. Heat transfer due to the movement of fluid over a warmer surface may be by way of convective heat transfer. In some aspects, the heat transfer may be expressed as:

$$q = hA ( {T}_{s} - {T}_{f} ) \qquad ( 1 )$$

where q is the heat transfer rate, h is the heat transfer coefficient, A is the surface area in contact with the fluid, Tₛ is the temperature of the surface (of the cold plate and/or heatsink), and T_{f} is the temperature of the fluid. In some aspects, representation (1) may be suitable for uniform temperature surfaces and fluids, with a constant heat transfer coefficient. In some aspects, a cold plate 210 may have variations in one or more (e.g., all) of these parameters (for example, the fluid flow near the inlet to the cold plate 210 may be laminar, but the fluid flow in the middle of the cold plate may be turbulent, which may affect the heat transfer coefficient). Representation (1) may be used to help determine the driving forces to increase convective heat transfer. For example, a higher difference in temperature between the cold plate 210 surfaces and the fluid, may result in a higher heat transfer rate. A higher heat transfer coefficient h may result in a higher heat transfer rate. In some examples, a larger surface area making contact with the fluid, may lead to a higher heat transfer rate.

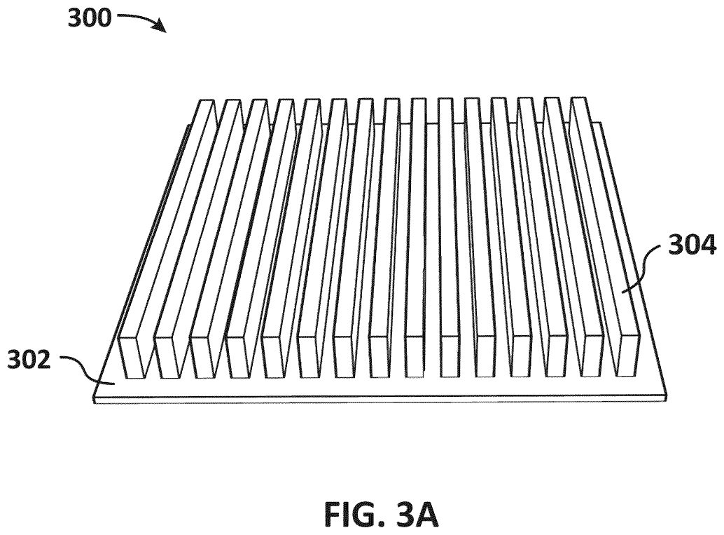

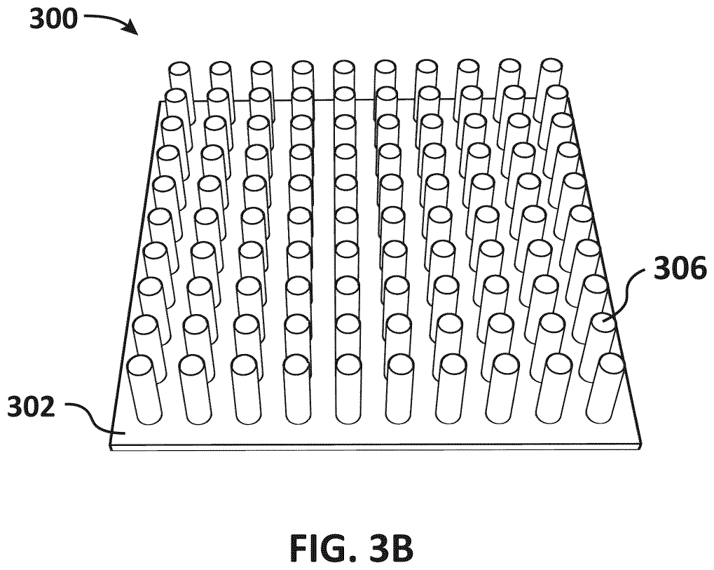

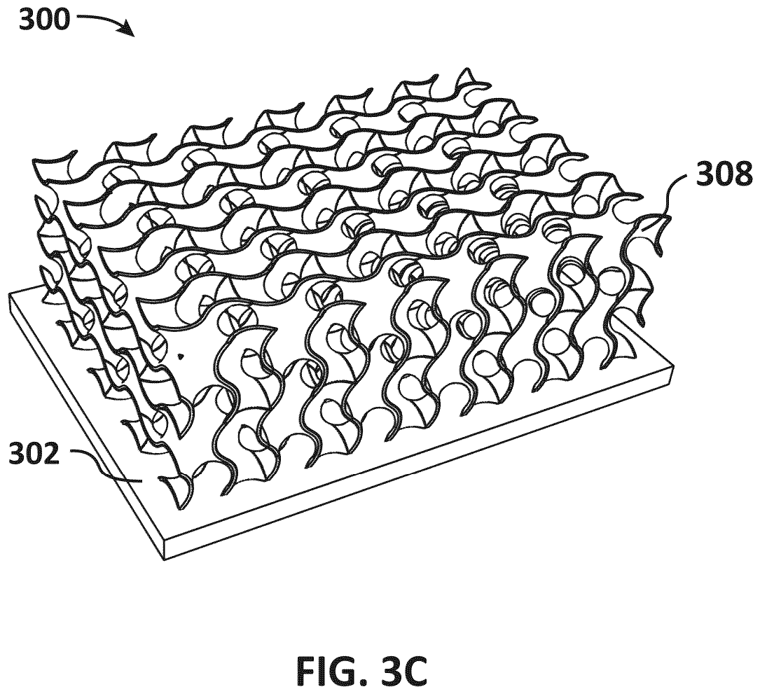

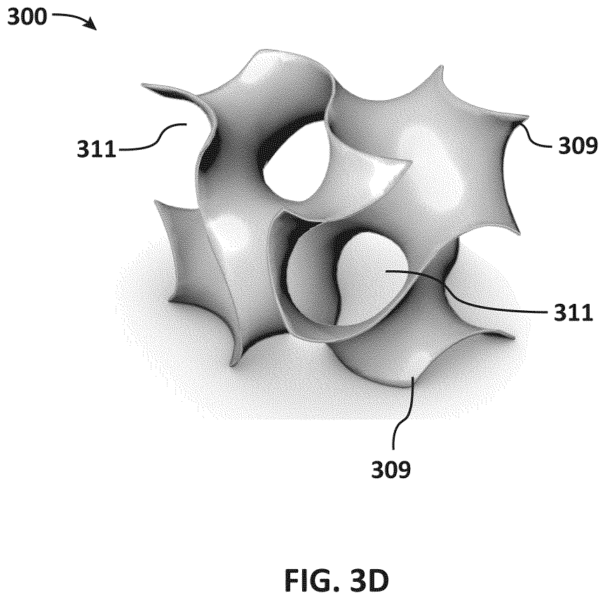

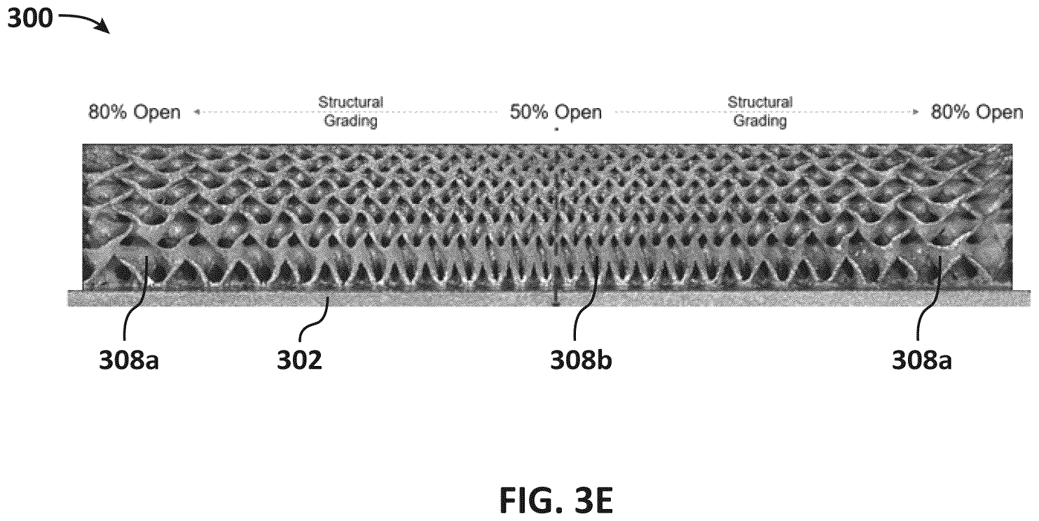

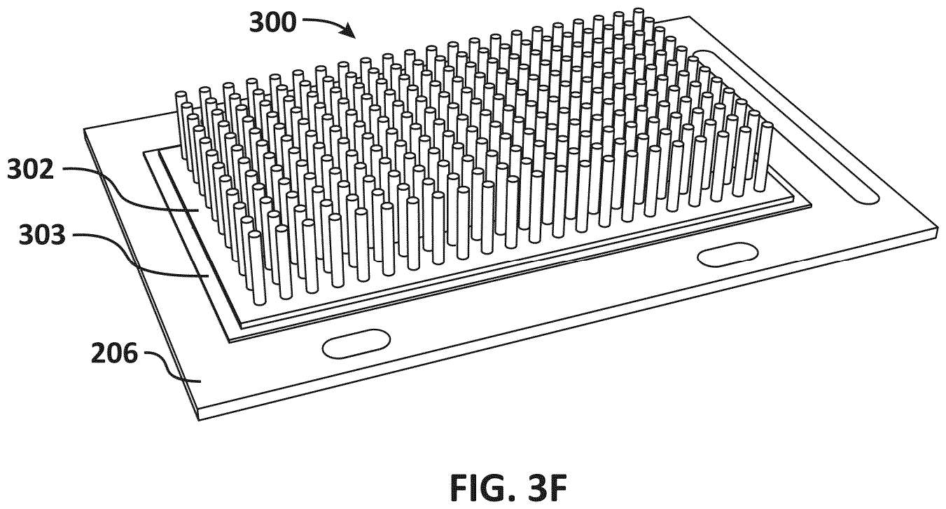

FIG. 3A illustrates an example configuration for a portion of a cold plate, such as cold plate 210, according to some embodiments. The portion of the cold plate may include a base 302 with fins 304. Examples of the disclosure may include a heat transfer geometry configured to transfer heat from the heater to the cold plate. In some examples, the heat transfer geometry may comprise fins 304 and/or base 302 of the cold plate. It can be understood that as the number of fins 304 may be increased (and the spacing between fins decreases, for a given size of a base 302) that the surface area for heat transfer may increase and/or the heat transfer rate from the cold plate may increase. In some examples, as the space between the fins 304 reduces, it may become increasingly harder for the fluid to flow in the narrower channels between the fins 304. In other words, the pressure drop across the cold plate may become higher, and a higher pumping power may be desired to push the coolant fluid through the fins 304. It may not be desirable to use higher capacity pumps to achieve a higher pumping power.

Although the fins 304 of FIG. 3A are elongated, with channels between them for fluid flow, the fins 304 could be in any shape or configuration that provides a heat transfer surface to accomplish heat transfer from the cold plate to the cooling fluid. FIG. 3B illustrates an example heat transfer geometry 300 that uses pin fins 306 arranged on a base 302, according to some embodiments. The cold plates having the example heat transfer geometries 300 shown in FIG. 3A and FIG. 3B can be made using one or more manufacturing methods, such as skiving, molding, pressing, casting, sintering, stamping, and the like.

FIG. 3C illustrates an example heat transfer geometry 300 comprising gyroid fins 308, according to some embodiments. FIG. 3D illustrates a close-up view of a unit cell of the gyroid fins 308 of FIG. 3C where the solid fin material 309 can be distinguished from the open space 311. Gyroid fins 308 may be difficult or impossible to manufacture with one or more manufacturing processes. In some cases, to increase the heat transfer area, a larger number of fins may be designed into a cold plate of a certain area. The larger number of fins may lead to increasing the fin area. In some examples, a larger number of fins may reduce the spacing between the fins. Reducing the spacing between fins (e.g., for the long rectangular fins 304 of FIG. 3A, or for the rows of pin fins 306 of FIG. 3B) may make it harder for fluid to flow between the fins, which may increase the pressure drop and may lead to an undesirable need for more pumping power. Some fin geometries, such as the gyroid fins of FIG. 3C and others, can achieve high heat transfer area without a severe pressure drop. Examples of the disclosure may use an additive manufacturing process to form the gyroid fins 308 that can deposit material in a stepwise or layer-by-layer fashion such that an appropriate geometry may be formed. This additive manufacturing may be accomplished by 3D printing, laser powder bed fusion, selective laser melting, maskless electroplating processes, or the like, for example. The gyroid fins 308 or similar heat transfer geometries 300 may have a high surface area per unit volume and/or may have the same heat transfer capability, such as fins 304 (of FIG. 3A), or pin fins 306 (of FIG. 3B), but with a lower pressure drop and lower required pumping power.

In some examples, (e.g., for more complex DUTs), it may be advantageous to have a heat transfer geometry 300 that varies across the base 302. For example, a DUT may comprise a system in package (SiP) or a multi-chip module (MCM) that includes one or more processor chips and/or multiple memory chips. The processor chip(s) may dissipate more power than the memory chips while undergoing some electrical tests. The higher power dissipation of the processor chip(s) may benefit from a higher amount of localized cooling for the processor chip(s) than for the memory chips. In other words, different heat transfer rates may be desirable in different zones of a cold plate 210 to support electrical testing of complex DUTs. An additive manufacturing process, such as that used to create the gyroid fins 308 of FIG. 3C, may be configured such that it can accommodate changes in the fin geometry in different zones of the cold plate 210.

FIG. 3E illustrates an example heat transfer geometry 300 comprising gyroid fins 308 having a plurality of geometries, according to some embodiments. For example, gyroid fins comprise gyroid fins 308a configured with 80% volume open (ratio of open space 311 to surface area) and gyroid fins 308b configured with 50% volume open. In some examples, the heat transfer geometry 300 may have variations in properties. For example, the heat transfer geometry 300 may comprise a graded geometry, where there may be a continuous progression from the geometry of gyroid fins 308a to gyroid fins 308b. The zones of a cold plate 210 comprising gyroid fins 308b may have a higher heat transfer rate and/or a higher cooling capability than zones comprising gyroid fins 308a, due to the difference in open area and surface area. For example, gyroid fins 308b may have less open space and more surface area, and gyroid fins 308a may have more open space and less surface area. Examples of the disclosure include a heat transfer geometry 300 located such that gyroid fins 308b are located in zones corresponding to a processor(s)-type DUT, and gyroid fins 308a are located in in zones corresponding to a memory chip(s)-type DUT. In some examples, the variations in the heat transfer geometry 300 may correspond to the variations in the DUT (e.g., the DUT may have different components or different power dissipations).

While FIG. 3E shows a progression of fin geometry or grading generally in a horizontal direction, the grading could alternatively be vertical, a combination of vertical or horizontal grading, or any other configuration of grading to achieve the desired thermal performance and pumping power objectives. Although gyroid fins 308 are shown in FIG. 3E, any fin geometry or combination of fin geometries may be used to form the heat transfer geometry 300 of the cold plate 210.

As previously discussed, to achieve the best thermal performance, it is desirable to directly integrate the cold plate 210 with the heater 206 and not just assemble them together temporarily (e.g., with clamps, vacuum hold-down, screws, or other means). One method of making a heater 206 is to use a ceramic material as a dielectric and structural support material and to create thick film traces on the ceramic dielectric that can be used for conducting current, and in some cases, for dissipating heat (e.g., a heater 206 may be formed by resistive traces). To integrate heater 206 with the cold plate 210, the two elements may be joined together by a low thermal resistance bond. In some embodiments, materials for forming the cold plate 210 may comprise metal materials, such as copper, aluminum, copper-tungsten, or other metals. It may be desirable to use a method to join the housing (e.g., comprising ceramic) of the heater 206 with the cold plate 210 (e.g., comprising metal). Although there are known methods of joining metals to ceramics, such as the so-called Direct Bond Copper (DBC) method of joining copper to an oxide ceramic like alumina (Al₂O3) or beryllia (BeO), these methods may not be suitable for certain applications. The DBC process, for example, requires a temperature of 1065° C. Because of the differing coefficients of thermal expansion (CTEs) of the copper (about 16 to 17 ppm/C) and alumina (about 8 to 11 ppm/C), the materials may contract by different amounts when cooling from the bonding temperature of 1065° C. to room temperature. Since the materials are bonded together, the different CTEs and large change in temperature may result in warping of the material or high interfacial stress that over time results in delamination of the materials. It may be desirable to find a process to join the cold plate 210 to the heater 206 at a reasonable temperature, such that the joining temperature is close to (e.g., higher than) the maximum temperature required during electrical testing (which might be in the range of 125° C. or 150° C.). Some soldering processes, silver or copper sintering, transient liquid phase joining, or other methods might be used to join the cold plate 210 to the heater 206 and may be in a temperature range of 250° C. or less, and/or may result in a low thermal resistance between the elements. In some cases, a brazing operation that is higher in temperature than 250° C., but significantly lower in temperature than the 1065°0 C. DBC process temperature may be used. In some embodiments, these types of joining processes may require a metal surface on each of the elements to be joined. In some examples, the cold plate 210 may already be formed from a metal material. In some examples, for the heater 206, a metal joining material may be deposited on one of the faces of the heater 206. Such a metallized surface could be provided by a thick film process during the original manufacturing of the heater 206, or could be provided in a subsequent process such as a physical vapor deposition (PVD), chemical vapor deposition (CVD), or a plating process.

As previously noted, the CTE difference between the heater 206 (e.g., comprising a ceramic material) and the cold plate 210 may impact integration of the heater 206 and cold plate 210. In some cases, it is desirable to choose a material for base 302 with a CTE close to the CTE of the heater 206, to facilitate joining of the base 302 to the heater 206. For example, the material for the base 302 to be joined to an aluminum nitride (AlN) ceramic-based heater 206 (with a CTE of 4.5 ppm/C) may comprise a WCu material such as W90Cu10 with a CTE of 6.5 ppm/C. A W90Cu10 material has a reasonably good thermal conductivity of 180 W/mK. Examples of the disclosure include other metal materials, such as Fe58Ni42 with a CTE of 5.3 ppm/C or Kovar with a CTE in the range of 5 to 6 ppm/C, or materials having low CTEs (e.g., near that of AlN). In some examples, the materials may have very low thermal conductivities (e.g., less than 20 W/mK). To reduce CTE effects (such as warping or delamination) on the integrated heater and cold plate, examples of the disclosure may include matching the CTE of the base 302 to the CTE of the heater 206. In some instances, the thickness of the base 302 can be reduced.

FIG. 3F shows a heat transfer geometry 300 with a relatively thick base 302 joined through a bonding material 303 to a ceramic-based heater 206 (without pins attached in this figure), according to some embodiments.

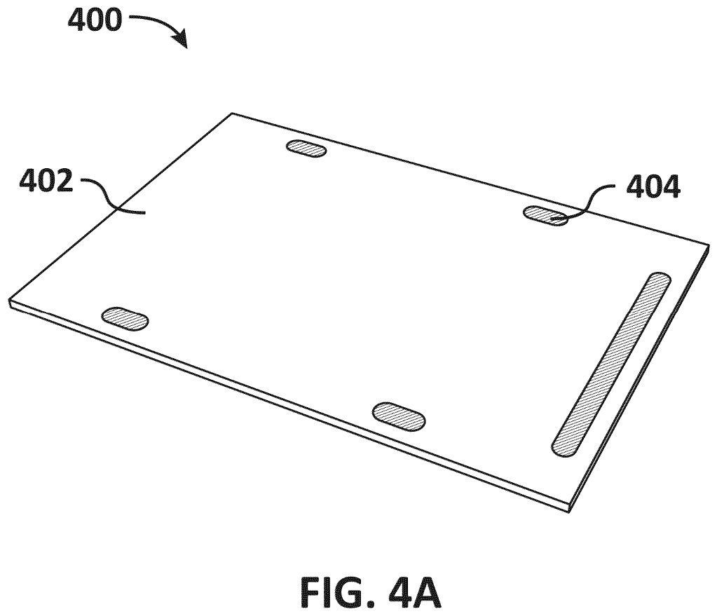

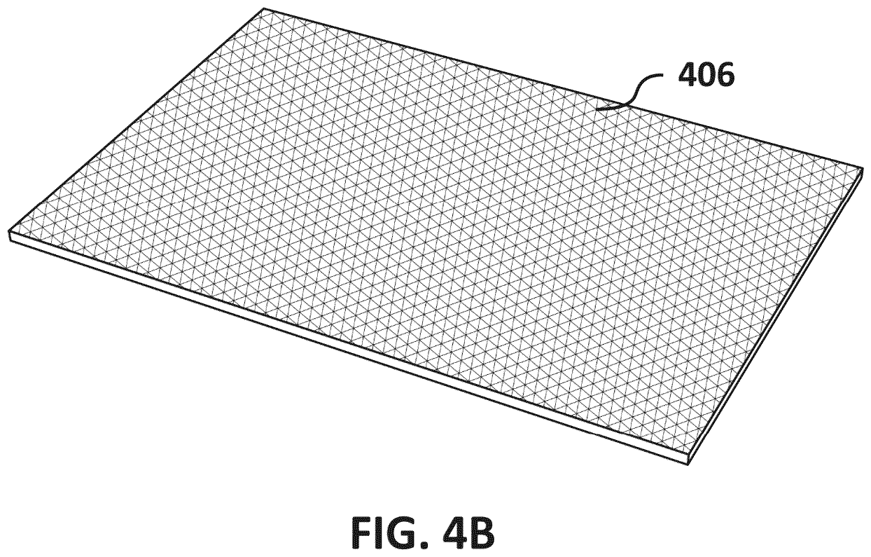

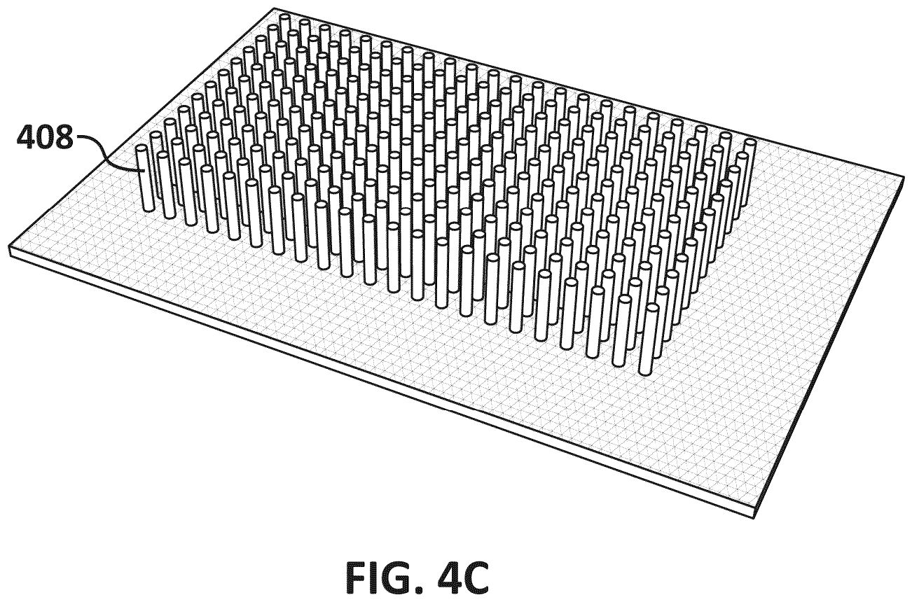

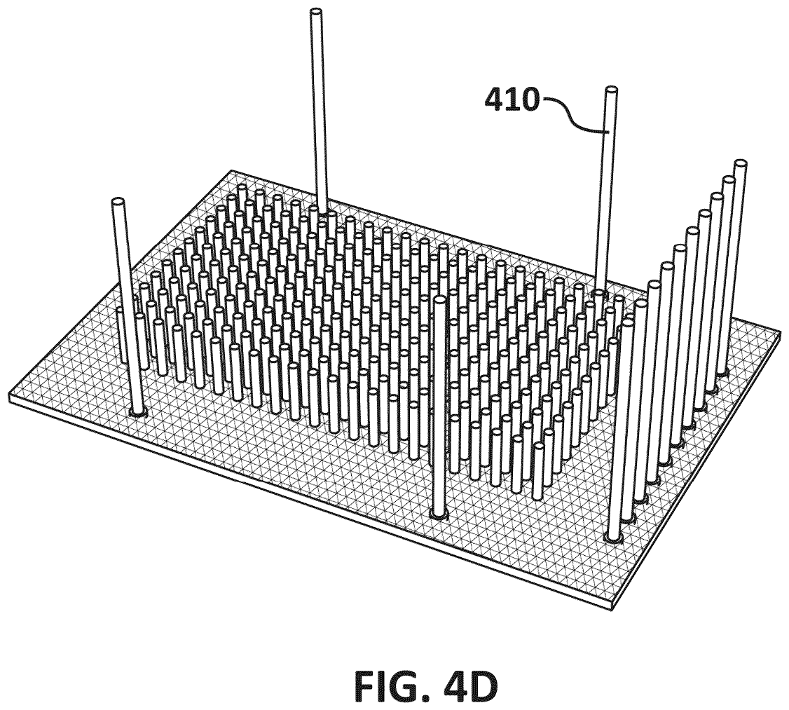

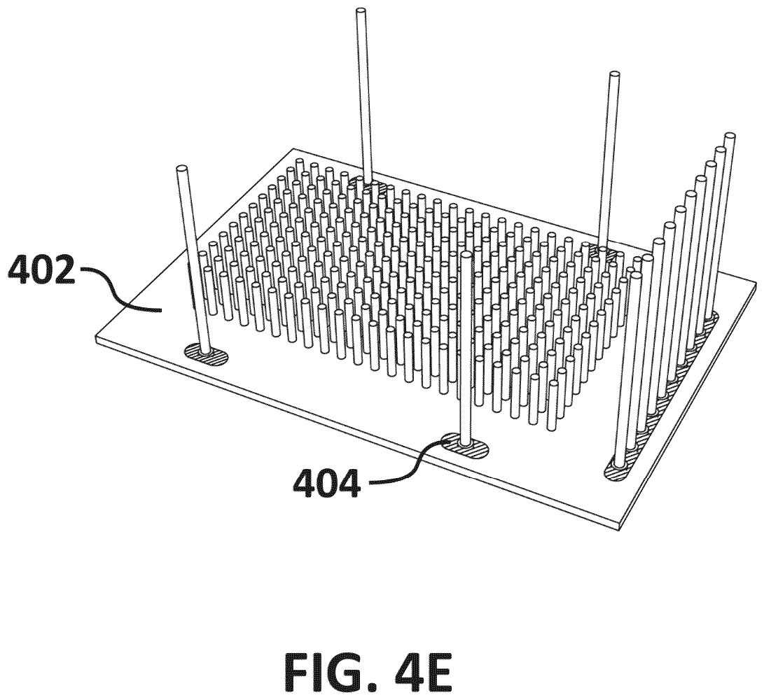

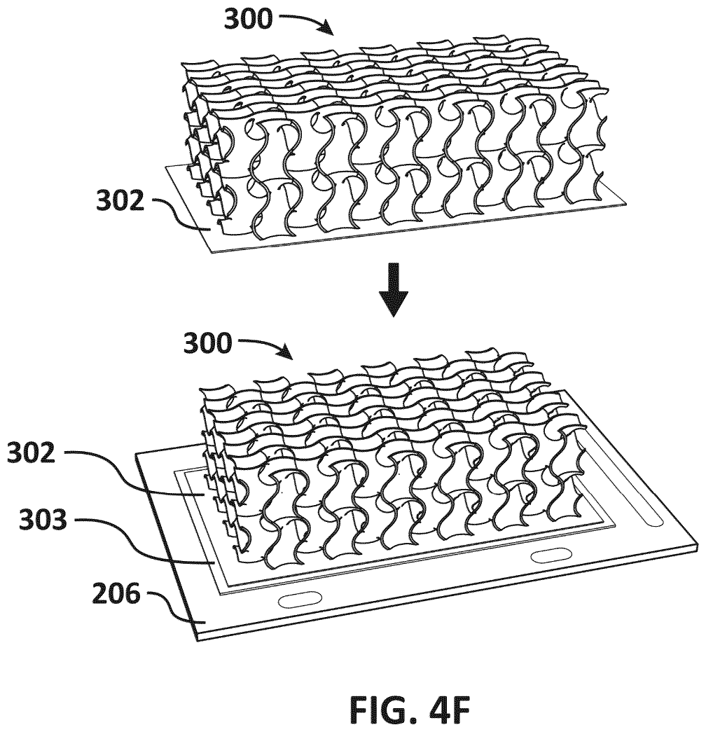

In the example embodiments described in the previous paragraphs, the heater 206 and cold plate 210 may be fabricated separately and then joined together with a joining process that results in an integrated heater and cold plate with a low thermal resistance between the elements. In some example, integrating the cold plate with the heater may comprise using the substrate of the heater 206 as a base for (e.g., an additive manufacturing process) depositing or growing the heat transfer geometry 300 directly on the heater 206, as illustrated in FIG. 4A to 4E.

In some examples, a dielectric material, such as ceramic, may be provided as a base. FIG. 4A illustrates a heater 400 comprising a ceramic dielectric material 402, such as Al2O3 or AlN, according to some embodiments. Pads 404 may be formed on the material 402 at locations where pins may later be attached. In some examples, pads 404 may be metallized. In some embodiments, the heater 400 may comprise conductive layers.

In some instances, at least one side of the material 402 may be covered by one or more metallization layers, such as metallization layer 406, as shown in FIG. 4B. The metallization layer 406 may comprise multiple layers, such as an adhesion and/or barrier layer, and a seed layer. The material for the adhesion/barrier layer may have good adhesion to the underlying ceramic material 402. In some examples, the material for the adhesion/barrier layer may be configured to prevent a seed layer or any other subsequent metallization layers from diffusing into the ceramic material 402. Example materials for adhesion/barrier layers may include, but are not limited to, titanium (Ti), chrome (Cr), tungsten (W), tantalum (Ta), titanium nitride (TiN), tantalum nitride (TaN), or a combination thereof. The adhesion/barrier layer may be deposited by a physical vapor deposition (PVD) process, such as sputtering, or other techniques such as atomic layer deposition (ALD), chemical vapor deposition (CVD), electroless plating, or the like.

The seed layer deposited may be copper (Cu), aluminum (Al), gold (Au), nickel (Ni), or the like. The seed layer may be deposited by a PVD process (such as sputtering), ALD, CVD, electroless plating, or etc. In some examples, the metallization layer 406 may comprise the adhesion/barrier and seed layers and can be used as a plating bus for electroplating subsequent structures on the metallization layer 406.

Embodiments comprise forming fins on the metallization layer 406. FIG. 4C illustrates fins 408 that have been electroplated (such as by a maskless, additive metal plating process) on the metallization layer 406, according to some embodiments. The fins 408 may form a heat transfer geometry 300 for transferring heat from a DUT or from the heater 400 to the cold plate (including its cooling fluid). Although the fins 408 are shown as cylindrical pin fins, the fins may be of any shape or geometry (such gyroids). At this stage, when the heat transfer geometry 300 has been formed, further processing could be performed. For example, another plating process, that forms fine asperities, could be applied to the heat transfer geometry 300. As another non-limiting example, an etching process could be applied to the heat transfer geometry 300 to create fine indentations or pores in the surface of the heat transfer geometry 300. In some examples, additional surface area could be created on the heat transfer geometry 300 and/or the surface texture of the heat transfer geometry 300 could be altered, which may improve heat transfer capability of the heat transfer geometry 300 due to, e.g., a larger surface area in contact with the coolant fluid, or improved heat transfer coefficient due to the altered texture of the surface of the heat transfer geometry 300. In some aspects, the heat transfer capability of the heat transfer geometry 300 may be improved by depositing a higher thermal conductivity material on the surface of the heat transfer geometry 300. For example, graphene (having a high thermal conductivity, e.g., 4000 W/mK or more than 10 times that of copper) can be deposited on a copper (Cu) material via a CVD process.

Although FIG. 4C shows a uniform array of fins 408 (e.g., the fins have the same spacing in both the X and Y directions) forming the heat transfer geometry 300, the heat transfer geometry 300 could be graded in the X, Y, or Z directions, or in any other manner. Grading refers to the surface area of the fins in a unit volume not being constant as you move from one region of the fins to another region in any of the X, Y or Z directions, or in any other manner that has a variation of fin surface area per volume.

Examples of the disclosure further include depositing a coating to improve the reliability of the heat transfer geometry 300. In some instances, materials in contact with a coolant fluid may be susceptible to corrosion. Additives may be added to the coolant fluid to help reduce corrosion. Additionally or alternatively, a coating such as nickel (Ni) coating can be deposited on the heat transfer geometry 300, to reduce corrosion from the heat transfer geometry 300 being exposed to a coolant fluid.

In some examples, connector pins 410 may be attached to the pads 404 on the heater 400, as shown in FIG. 4D. The connector pins 410 may be attached by a soldering, brazing, sintering, transient liquid phase bonding, or other attachment process. The connector pins 410 may comprise a metal material and may also comprise a coating on the pin that prevents oxidation of the surface. The diameter, spacing and location of connector pins 410 are designed so that the connector pins 410 can mate with a complementary connector or socket to provide an electrical connection. Connector pins 410 may be long enough to clear elements of the cold plate 210 so that they can mate with a connector or socket.

The metallization layer 406 may be etched away. FIG. 4E illustrates the heater 400 after the metallization layer 406 has been etched away, according to some embodiments. In some examples, the metallization layer 406 is thin relative to the fins 408 or connector pins 410, and as a result, the metallization layer 406 may be etched away without adversely affecting the fins 408 or connector pins 410. Through the processes depicted in FIGS. 4A through 4E the heater 400 has been transformed into a heater 400 with an integrated heat transfer geometry 300.

Although the processes shown in FIG. 4B through 4E do not use any masking steps (such as photolithographic steps using a photoresist material and a mask), in some examples, masking steps for one or more processes may be appropriate.

In some examples, the heat transfer geometry 300 may be formed on a separate base 302. The heat transfer geometry 300 and base 302 may be formed to the heater 206 using a bonding material 303. For example, for previously discussed reasons, a thin base 302, such as a thin plate or a foil, with a CTE close to the CTE of the heater 206 (e.g., ceramic), such as a W90Cu10 material could be used as a base 302 upon which to form the build-up, additive or plated heat transfer geometry 300. This thin base 302 with its heat transfer geometry 300 could be joined through conventional joining techniques (such as soldering processes, silver or copper sintering, transient liquid phase joining, brazing, or other suitable process) to the heater 206, as shown in FIG. 4F. The heat transfer geometry 300 shown in FIG. 4F is shown as a complex, gyroid geometry, which can be created with a maskless, additive process. Any heat transfer geometry 300 that can be created by a build-up, additive or room temperature plating process could be used. Furthermore, the base 302 can be electrically coupled to traces or pads on or in the heater 206, such as by an electrically conductive bonding material 303. When used in an application, the base 302 could be connected to a ground potential.

Another variation to the aforementioned direct build-up process (FIG. 4A-4E) or the process of constructing a heat transfer geometry 300 on a base 302 and then attaching that to the heater 206 (FIG. 4F) is to take elements from each of these processes to form the integrated heater and cold plate. A first step could be attaching a base 302, such as a WCu base with a CTE close to the CTE of a heater 206 (e.g., a ceramic heater), to the heater 206 using a bonding process (such as soldering processes, silver or copper sintering, transient liquid phase joining, brazing, or other suitable process) using a bonding material 303. The base 302 then could be used to build up the heat transfer geometry 300 in-situ on heater 206, such as by using an electroplating process. In some embodiments, a higher temperature joining process may be used for joining the base 302 to the heater 206, while a lower temperature build-up process (such as a room-temperature electroplating process) could be used to form the heat transfer geometry 300. This multi-step process may be used to reduce the stress induced by the heat transfer geometry 300 compared to an alternative higher temperature joining process.

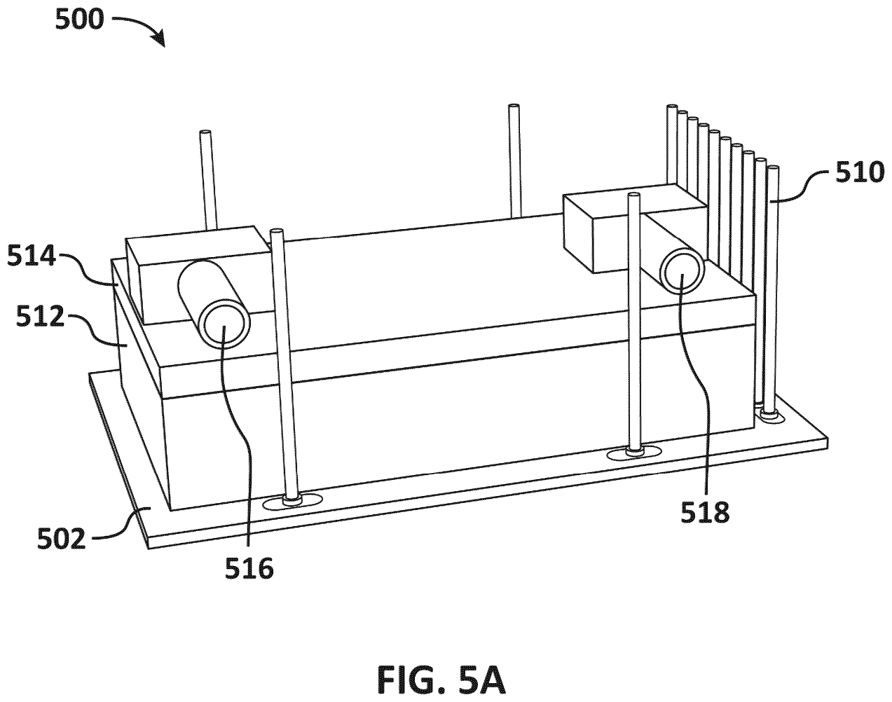

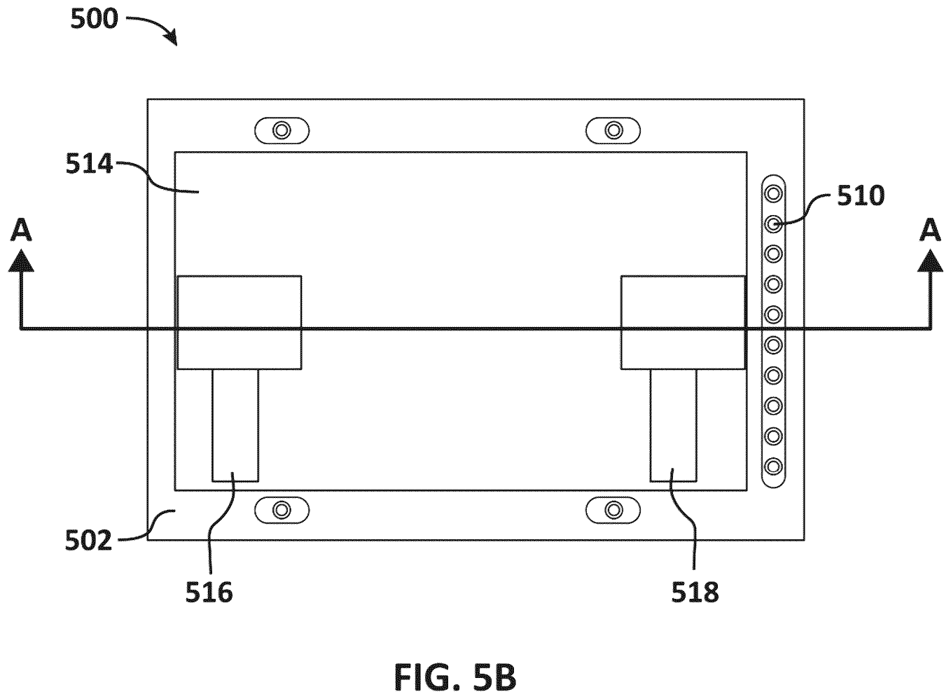

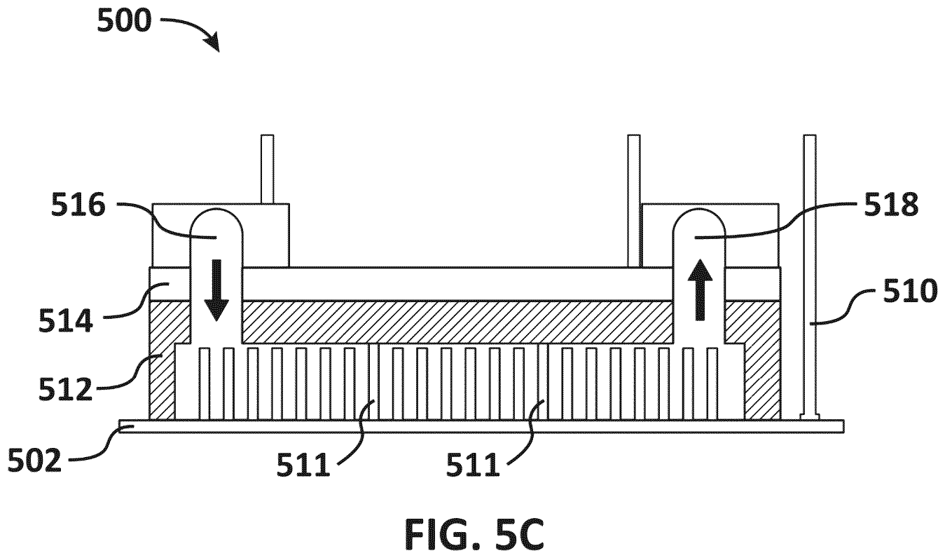

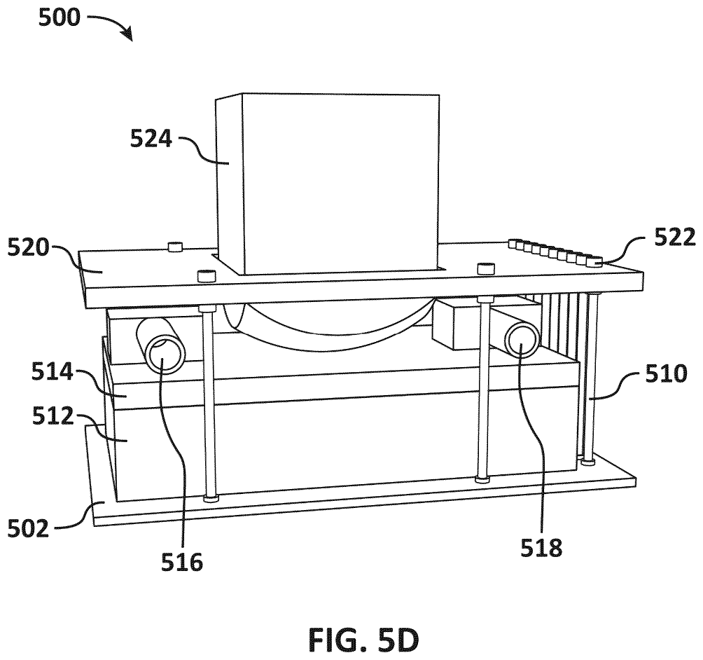

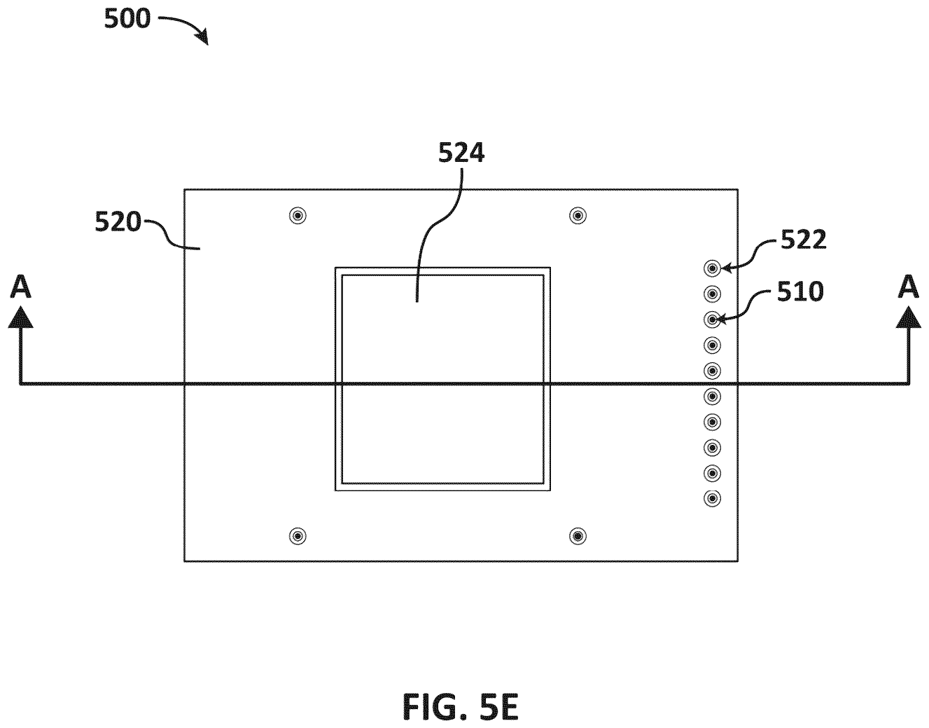

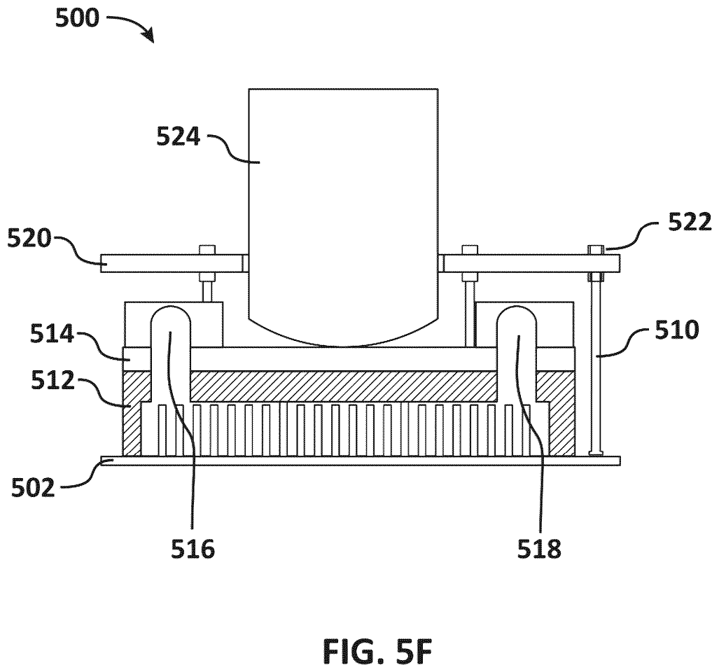

FIG. 5A shows the integrated heater 400 and heat transfer geometry 300 of FIG. 4E with further processing to form an integrated heater and cold plate 500, according to some embodiments. A cover structure comprising a first cover 512, a second cover 514, a fluid inlet 516 and a fluid outlet 518 has been assembled onto the heater 502.

FIG. 5B is a top-down view of the integrated heater and cold plate 500 of FIG. 5A, according to some embodiments. FIG. 5B displays section line A-A that is used to cut through the integrated heater and cold plate 500 to yield the section view shown in FIG. 5C.

FIG. 5C shows a section view of the integrated heater and cold plate 500, according to some embodiments. Arrows indicate the fluid flow from the fluid inlet 516 and into the fluid outlet 518. The fluid flows from the fluid inlet 516 (as shown by the bold downward arrow), through the heat transfer geometry 300, and then out of the fluid outlet 518 (as shown by the bold upward arrow), thus affecting a transfer of heat from the fins of the heat transfer geometry 300 to the fluid. Although the cover structure of FIG. 5C comprises a first cover 512 and a second cover 514 as multiple pieces, the cover structure may be comprised of a single piece. The cover structure creates a fluid-tight cavity around the heat transfer geometry 300. One possibility provided by a cover structure that comprises a first cover 512 and a second cover 514 is that the covers may be joined together by quick-disconnect fluid couplings. In such a fashion, the first cover 512 and second cover 514 could be separated without loss of a fluid. This could allow for easily changing the integrated heater and cold plate 500 within a test system. The material of the first cover 512, the second cover 514, or both may be chosen to have a CTE that is similar to the CTE of the heater 502. By choosing cover materials and with CTEs close to the CTE of the heater, warpage that may be induced when the covers are coupled to the heater 502 (e.g., at a high temperature and then cooled to room temperature) can be minimized. The first cover 512 can be attached to the heater 502 by soldering, brazing, sintering, transient liquid phase bonding, adhesive bonding, or other bonding processes. As shown in FIG. 5C, structural pins 511 or other structures can be included within the heat transfer geometry 300 that attach to the first cover 512, to provide a structural link between the heater 502 and the central regions of the first cover 512, which can alleviate any deformation of the cover 512 or heater 502 due to the fluid pressure within the cavity of the cover 512 or due to any force applied externally to the cover 512 or heater 502.

FIG. 5D shows additional components added to the integrated heater and cold plate 500 of FIG. 5, according to some embodiments. A Printed Circuit Board (PCB) 520 that comprises connectors 522 couples to the pins 510 of the integrated heater and cold plate 500. The PCB 520 may be configured to house the components required to create a thermal controller. There is a force applicator 524 also shown in FIG. 5D. The force applicator 524 can be used to apply a force to the integrated heater and cold plate 500, which in turn can apply a force to the DUT (such as DUT 200 of FIG. 2A) so that the DUT properly couples with the socket (such as socket 202 of FIG. 2A).

FIG. 5E is a top-down view of the integrated heater and cold plate 500, according to some embodiments. Section line A-A is indicated in this view.

FIG. 5F is a section view of integrated heater and cold plate 500 cut along the section line A-A indicated in FIG. 5E, according to some embodiments. In this view, the PCB 520 can be seen to have a hole that allows the force applicator 524 to engage directly with the second cover 514. FIG. 5F also shows how pins 510 engage the connector 522 so that the pins 510 can be electrically coupled to the PCB 520.

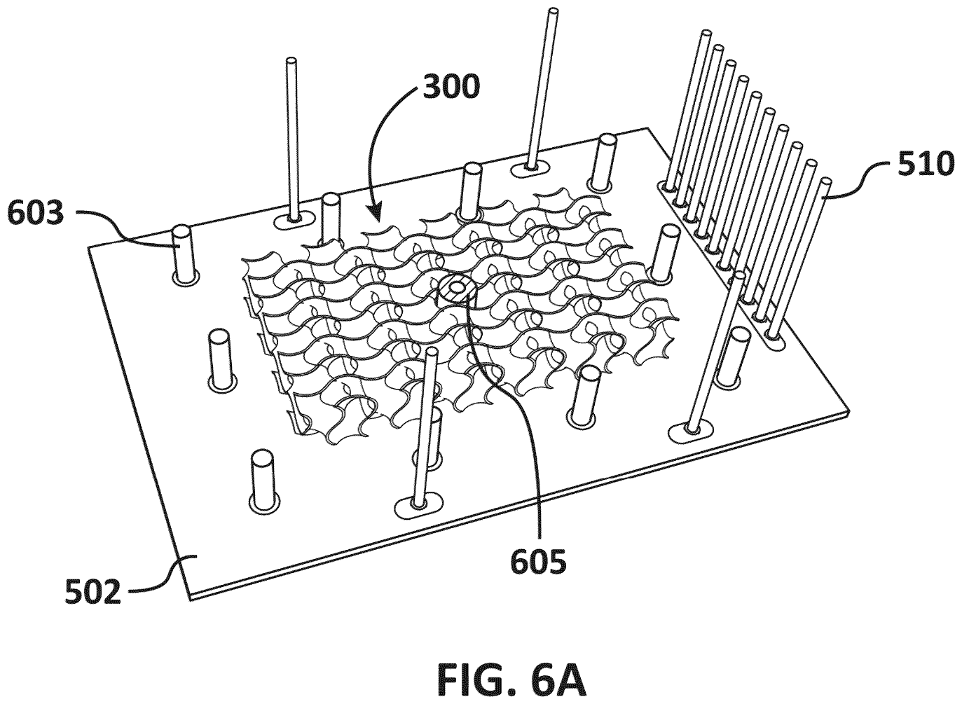

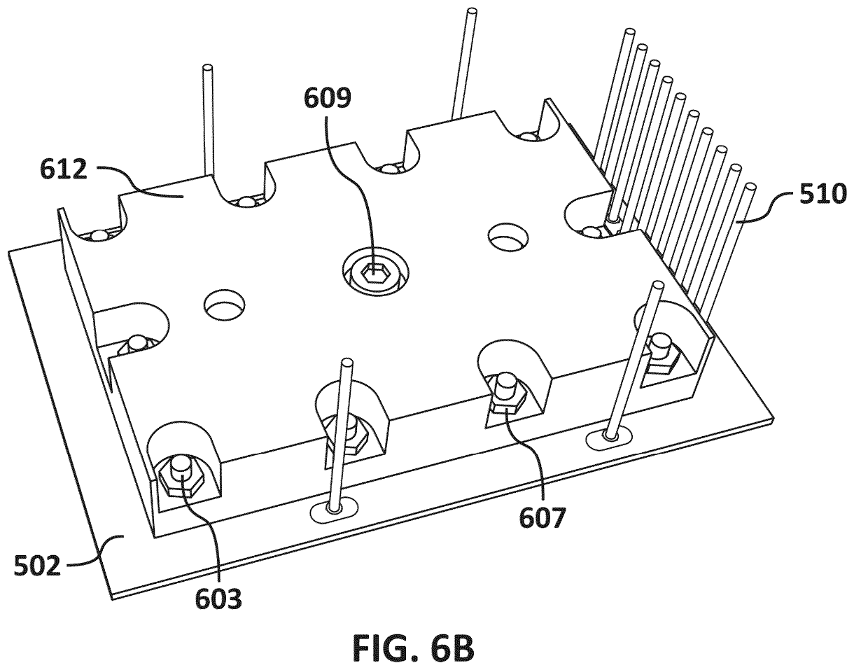

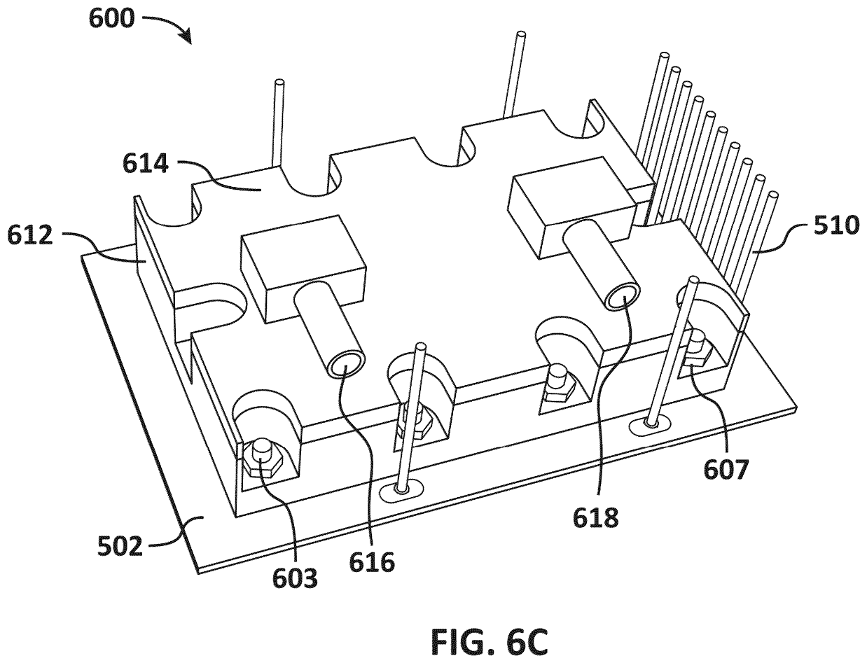

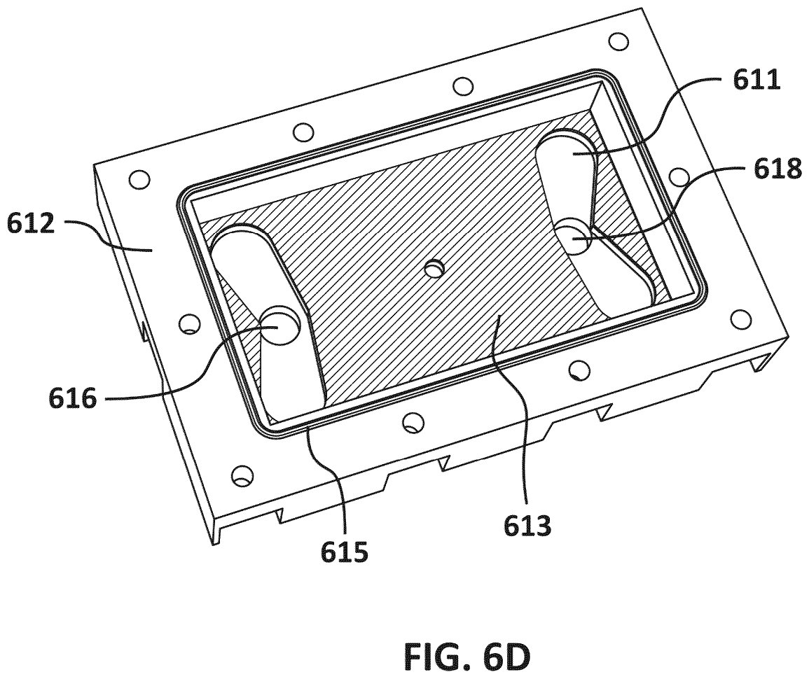

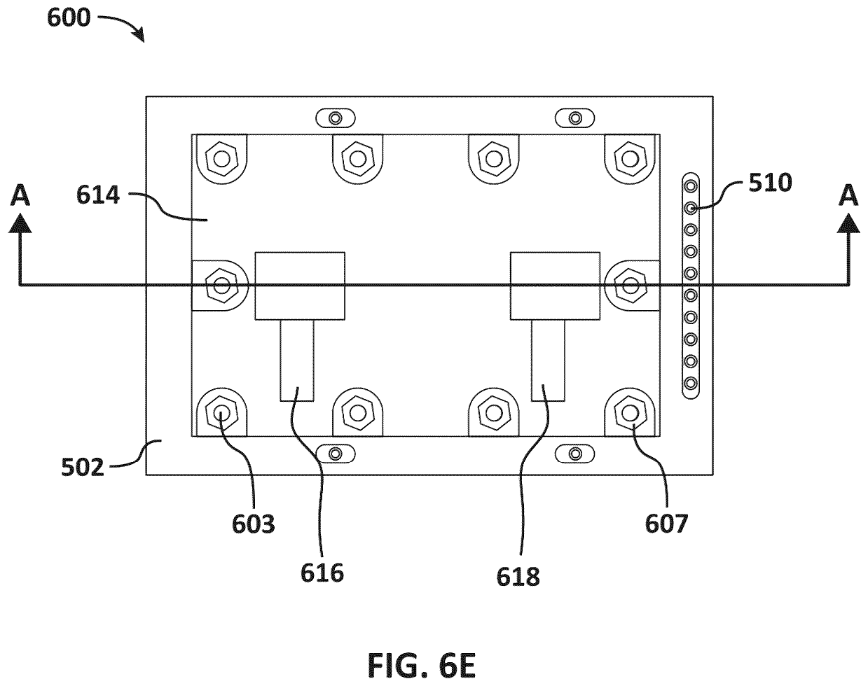

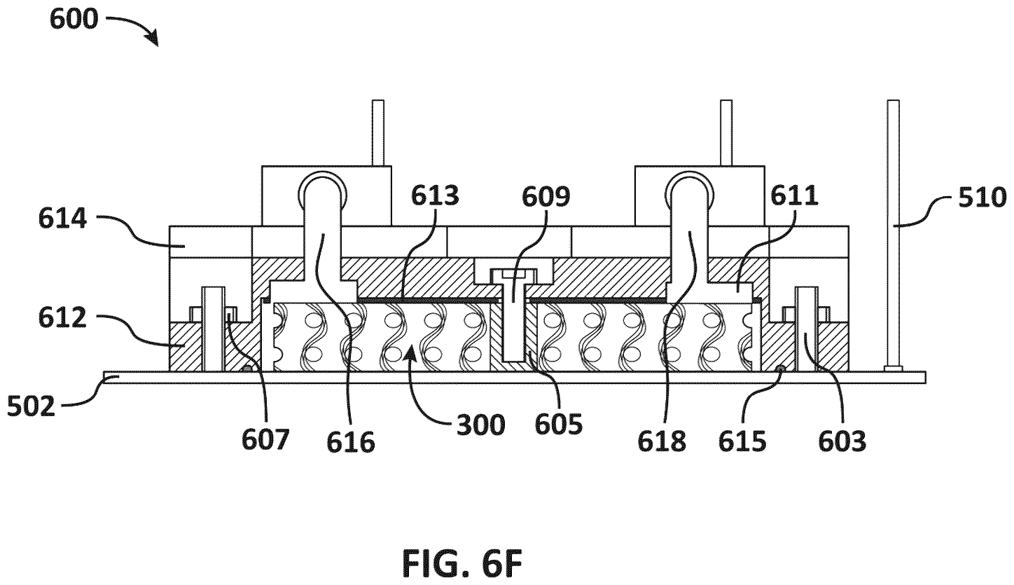

In some embodiments, the first cover 512 can be attached to the heater 502 by screws, clamps, or other mechanical attachment means. FIG. 6A shows a heater 502 upon which a heat transfer geometry 300 has been created, according to some embodiments. Although the heat transfer geometry 300 shown in the figure is a gyroid, any suitable heat transfer geometry 300 could be used. In the region of the heat transfer geometry 300, there is a mechanical support structure 605, which in this case is a solid post with a threaded hole, although other configurations could be provided, such as a helicoil or threaded insert. In addition to pins 510 being affixed to the heater 502, there are also threaded studs 603 affixed to the heater 502.

FIG. 6B depicts the assembly of FIG. 6A with the addition of a first cover 612, according to some embodiments. Unlike the first cover 512 of FIG. 5 which was affixed to the heater 502 in a permanent fashion, first cover 612 is mechanically attached to the heater 502 and can be removed from the heater 502. In the example of FIG. 6B, the first cover 512 is attached to the heater 502 using threaded studs 603 and corresponding nuts 607 as well as screw 609, which is screwed into the mechanical support structure 605 shown in FIG. 6A. Although this figure shows the use of threaded studs 603, nuts 607, and screws 609 to attach the first cover 512 to the heater 502, any suitable means of non-permanent, mechanical attachment could be used.

FIG. 6C depicts the assembly of FIG. 6B with the addition of a second cover 614, according to some embodiments. In some cases, second cover 614 may be coupled with first cover 612 using quick disconnect fluid couplings. The second cover 614 includes a fluid inlet 616 and a fluid outlet 618. Although FIG. 6C depicts the cover structure as a combination of a first cover 612 and a second cover 614, it will be understood that a single cover could be used.

FIG. 6D shows a perspective view of the bottom of the first cover 612, according to some embodiments. To help achieve a fluid-tight seal, while still allowing for non-permanent, mechanical assembly, the first cover 612 may be combined with elements that may be used to inure fluid-tight seals, such as gasket or O-ring 615. Furthermore, the first cover 612 may have recesses, grooves, walls, protrusions, or other features that may aid in directing the flow of the cooling fluid. In FIG. 6D, recesses 611 are shown that couple to the fluid inlet 616 and fluid outlet 618. Gasket 613 is shaped to match the outline of recesses 611.

FIG. 6E shows a top-down, plan view of the integrated heater and cold plate 600, including a section line indicator A-A, according to some embodiments.

FIG. 6F shows a section view of the integrated heater and cold plate 600, cut along the section line indicator A-A of FIG. 6E, according to some embodiments. This figure shows one example of how an O-ring 615 and gasket 613 can be used to form fluid-tight seals between the first cover 612 and the heater 502 and heat transfer geometry 300 (including the mechanical support structure 605), respectively. This section view also shows how the fluid inlet 616 and fluid outlet 618 couple to the recesses 611 in the first cover 612. The threaded studs 603 and corresponding nuts 607 along with the screw 609 and corresponding mechanical support structure 605 allow for the mechanical assembly of the first cover 612 to the heater 502. The mechanical support structure 605 and screw 609 can bind the first cover 612 to the heater 502 and alleviate deflection of either the first cover 612 or heater 502 due to fluid pressure inside the cavity of the integrated heater and cold plate 600.

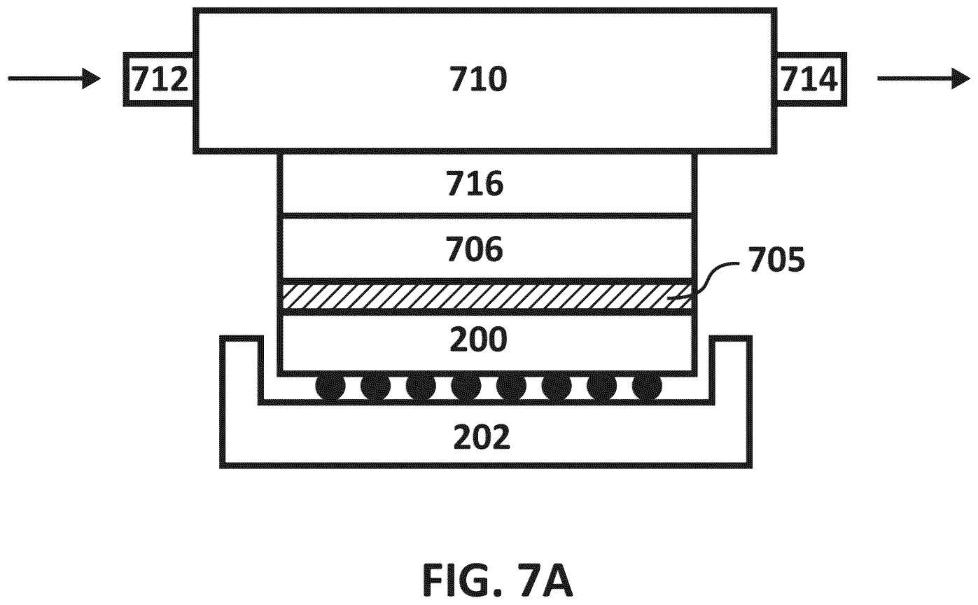

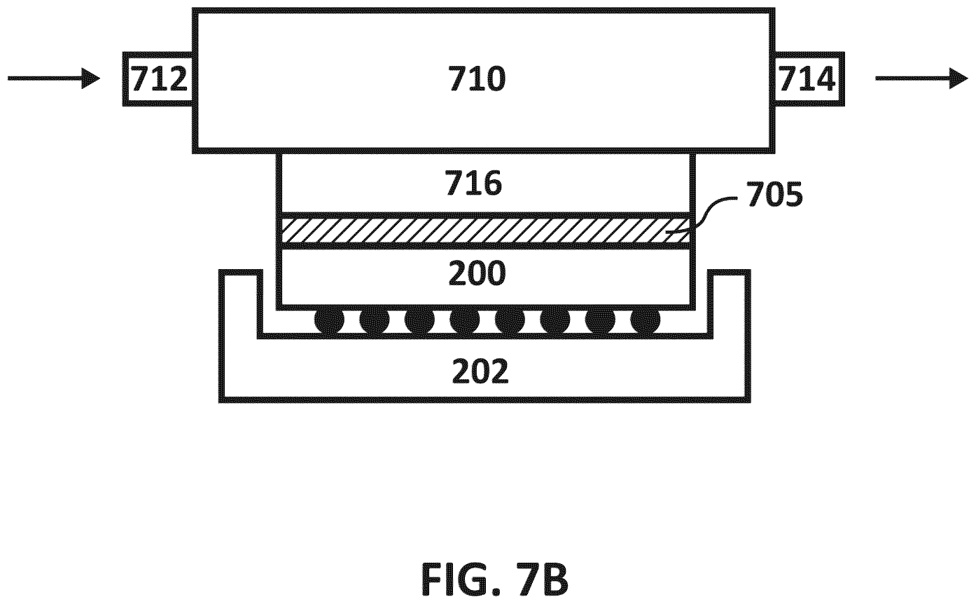

FIG. 7A shows a thermoelectric cooler (TEC) 716 that has been incorporated between the heater 706 and the cold plate 710 (cooled by a cold fluid that enters an inlet 712 to the cold plate 710 and exits via an outlet 714 from the cold plate 710). A TEC 716 can increase the cooling capacity of the integrated heater and cold plate. The TEC 716 may be permanently attached to the heater 706, such as by soldering or brazing or other attachment process or in some cases the TEC 716 and the heater 706 are fixedly attached, such as through a clamp or screws or other means and can be dis-assembled. In some examples, the heater 706 may be a TEC. FIG. 7A shows an optional TIM 705 between the DUT 200 and the heater 706.

FIG. 7B shows a TEC 716 that attaches directly to the cold plate 710 (or an adapter coupled to the cold plate 710), according to some embodiments. In some embodiments, a heater may not be included.

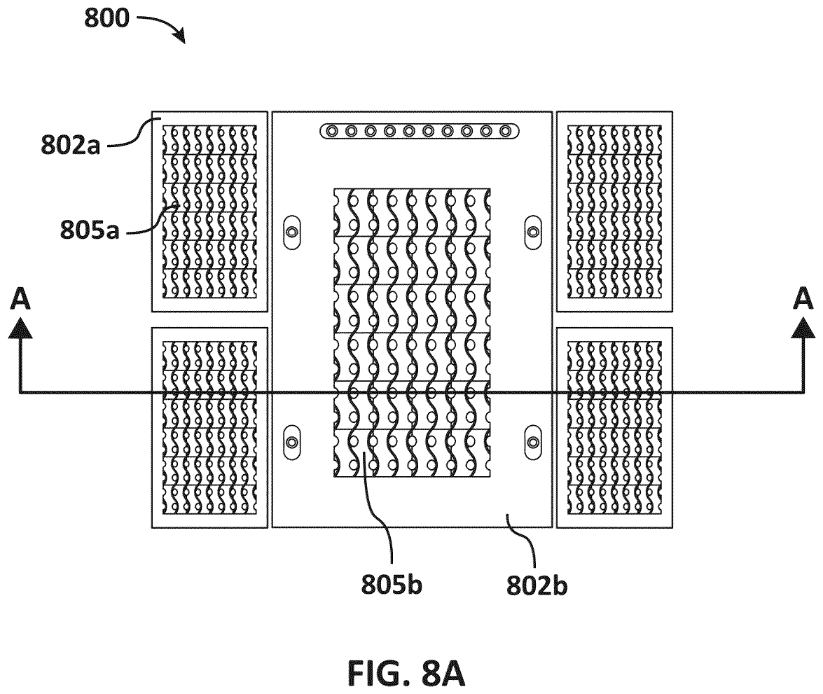

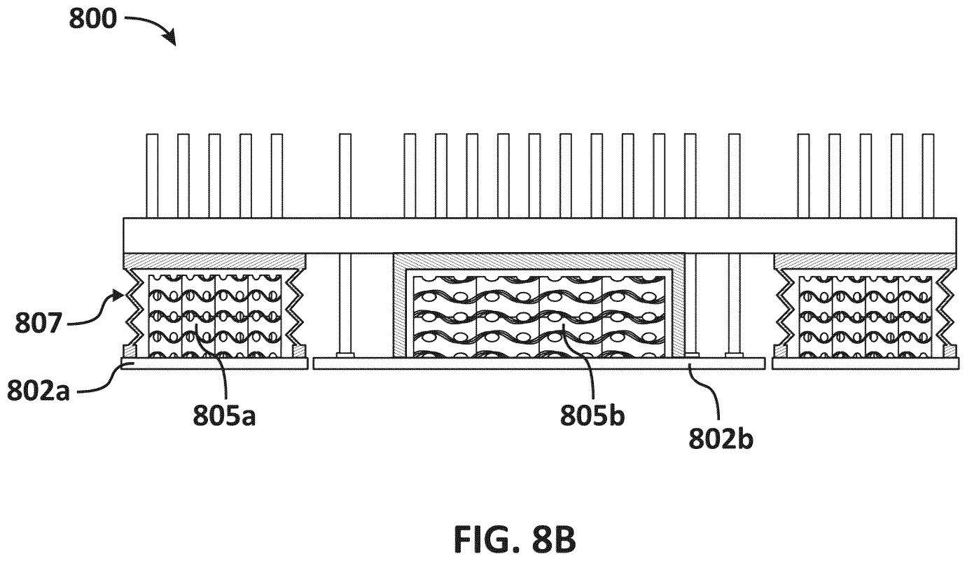

FIG. 8A shows thermal control component 800 that is comprised of four smaller heaters 802a and one larger heater 802b, according to some embodiments. The smaller heaters 802a have corresponding integrated heat transfer geometry 805a and the larger heater 802b has corresponding integrated heat transfer geometry 805b. Note that the cover structure on the cold plates is not shown in the figure. This type of configuration could be useful when the DUT comprises an MCM or SiP package with chips or other components that require heating or cooling at different temperatures or at different rates. For example, the smaller heaters 802a could correspond to memory chips on the DUT, while the large heater 802b may correspond to a processor on the DUT. The thermal control component of FIG. 8A could be configured such that the smaller heaters 802a and the larger heater 802b are independently controllable. In some embodiments, the cooling of the smaller integrated heat transfer geometries 805a and the larger integrated heat transfer geometry 805b could be independently controlled.

FIG. 8B is a section view of FIG. 8A along section line A-A, according to some embodiments. The smaller integrated heaters 802a and cold plate geometries 805a of FIG. 8B may be thermally independent of the larger integrated heater 802b and cold plate geometry 805b. Additionally or alternatively, the smaller integrated heaters 802a and cold plate geometries 805a, and larger integrated heater 802b and cold plate geometries 805b, may be mechanically independent. For example, the memory chips on an MCM or SiP package may have a height that is different from the height of the processor or be at an angle to the substrate they are mounted to at a different angle from the angle of the processor. To accommodate these different heights or angles, one or more of the integrated heaters 802a and cold plate geometries 805a may be mechanically compliant. FIG. 8B shows a compliant element 807 that allows the smaller integrated heaters 802a and cold plate geometries 805a to be compatible with each other. The compliant element 807 may be a bellows or any other structure, for example, that allows the smaller integrated heaters 802a and cold plate geometries 805a to be thermally coupled to each other, while also maintaining a fluid-tight cavity.

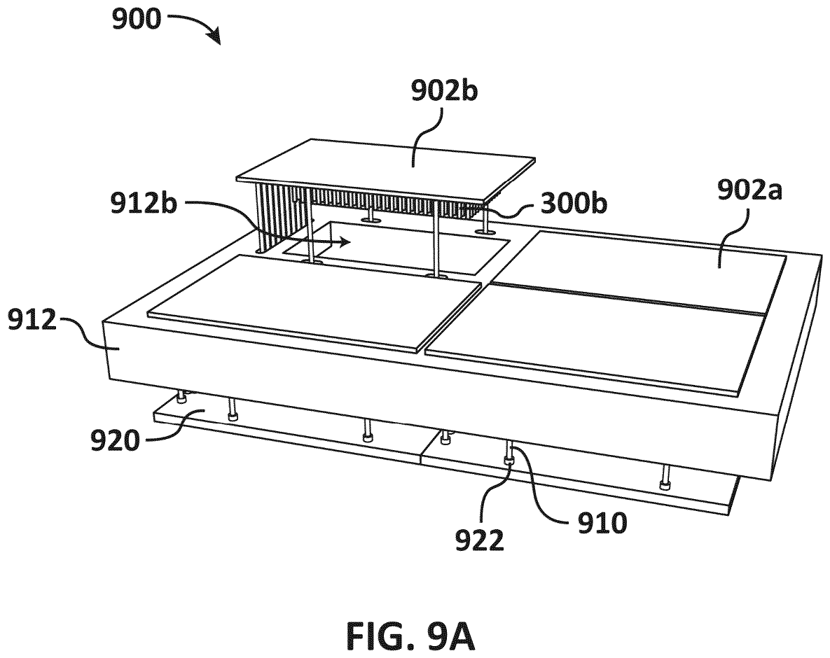

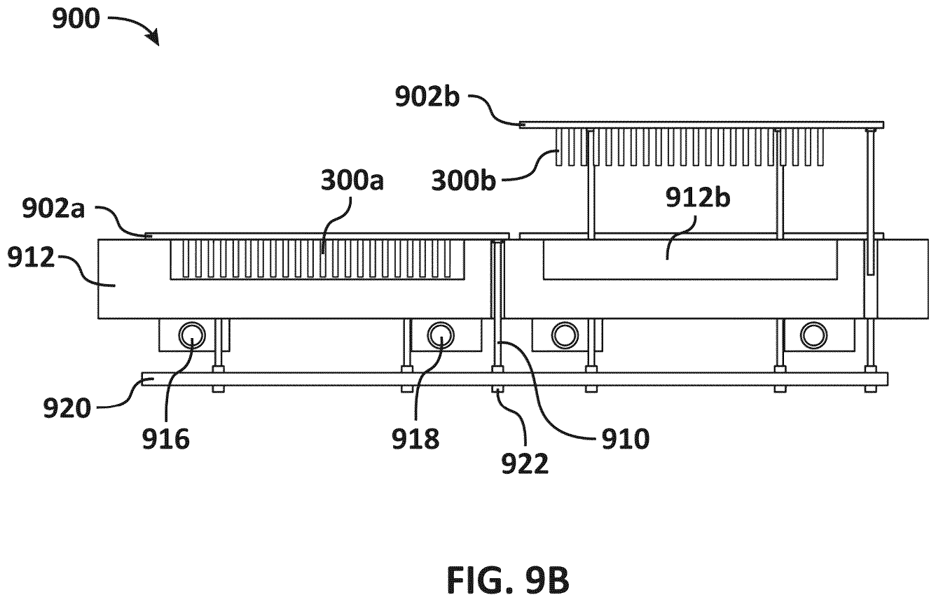

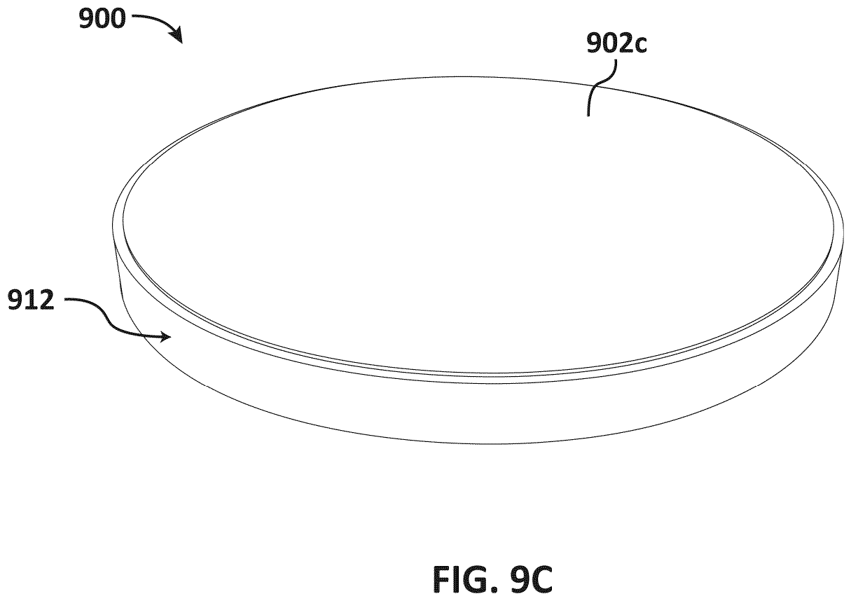

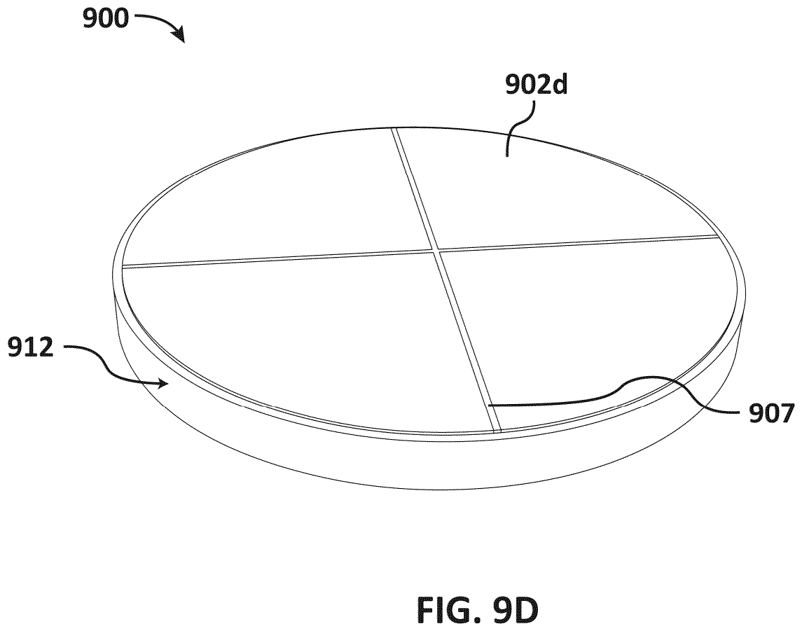

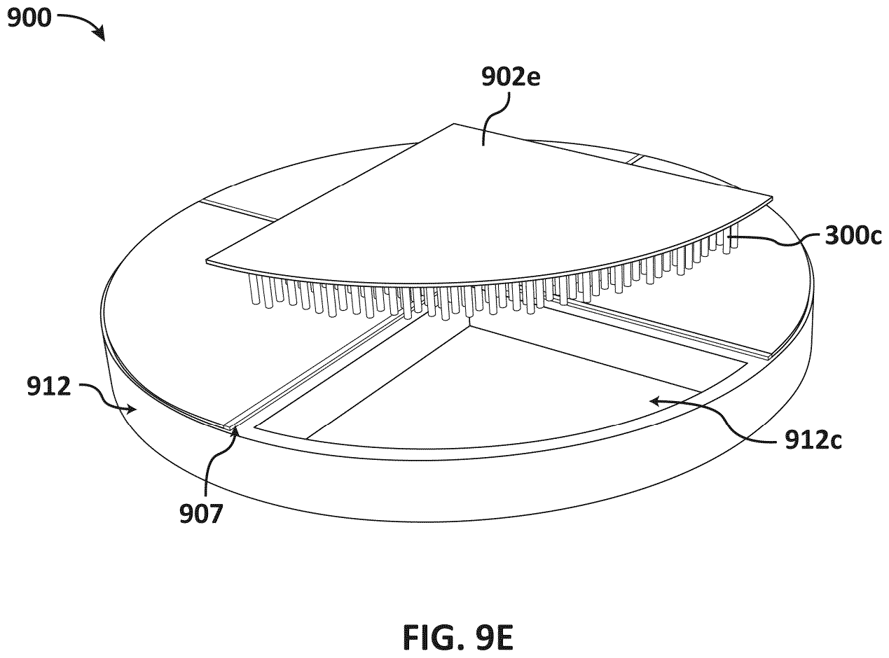

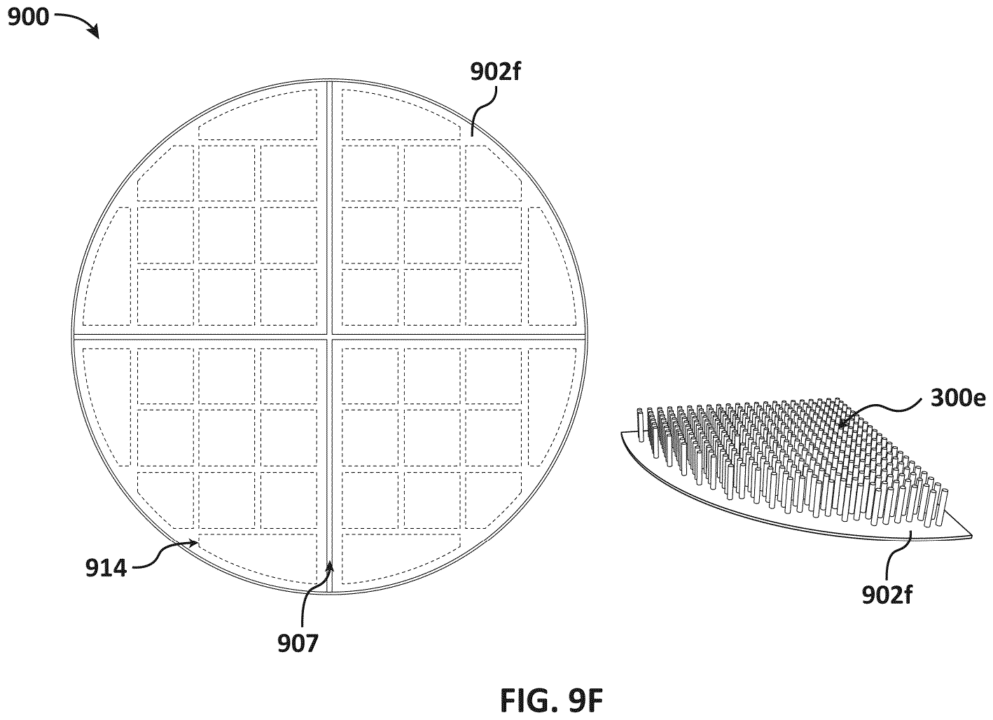

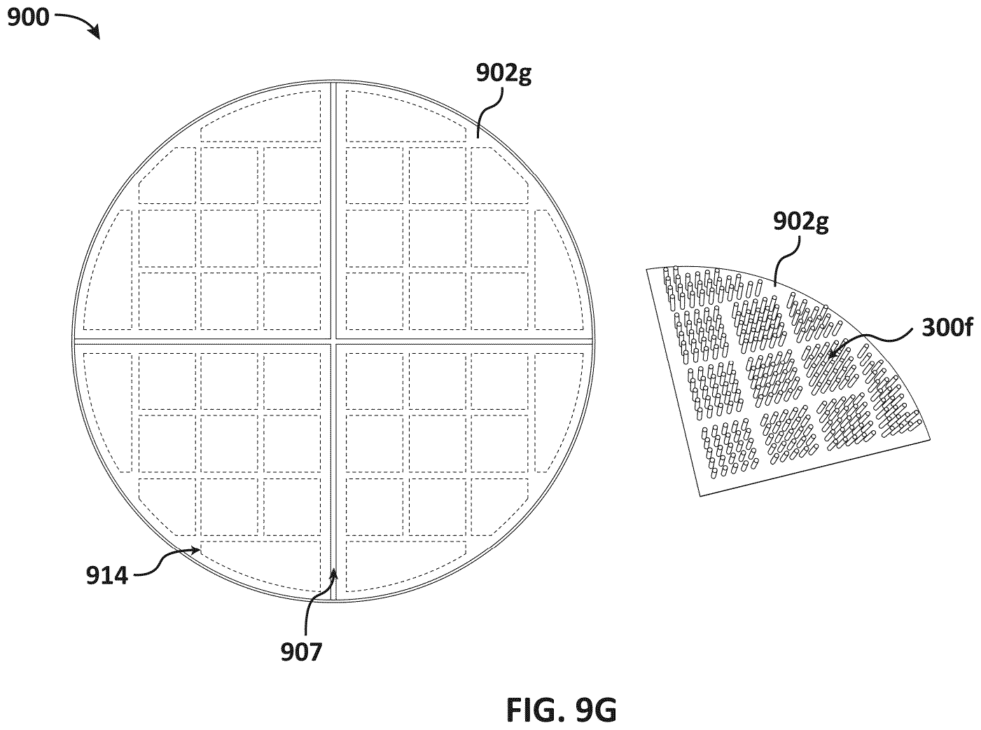

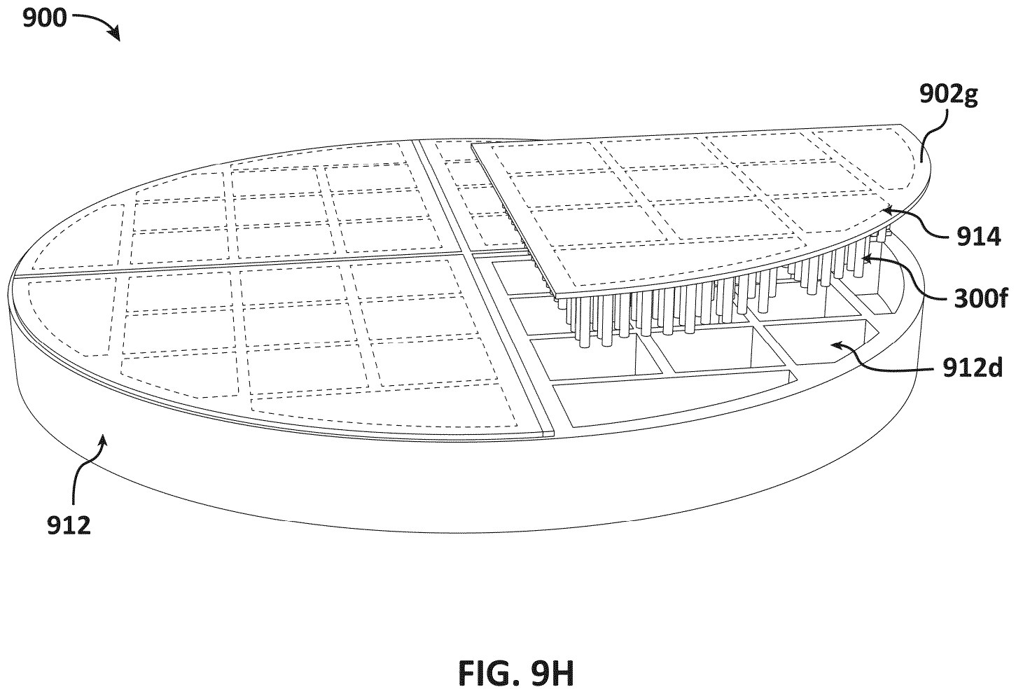

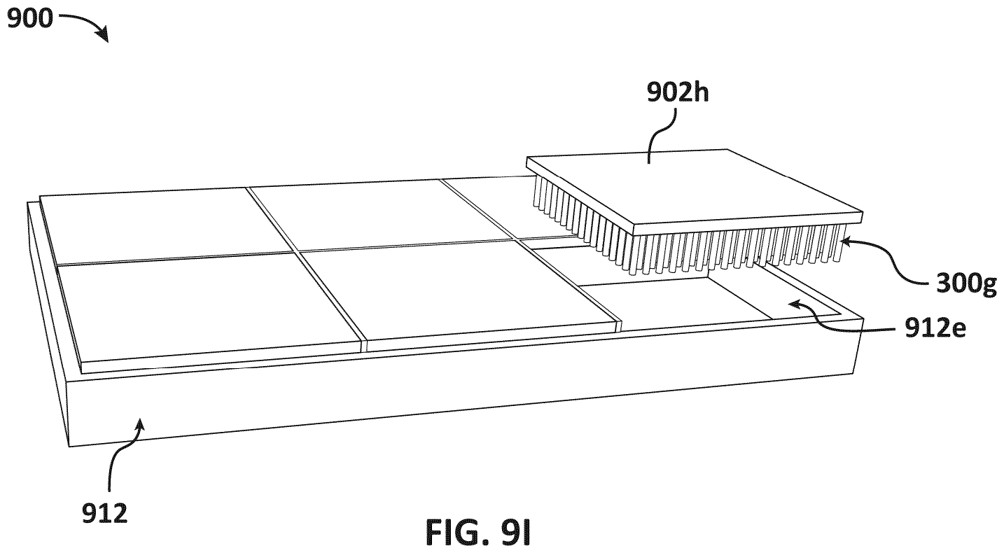

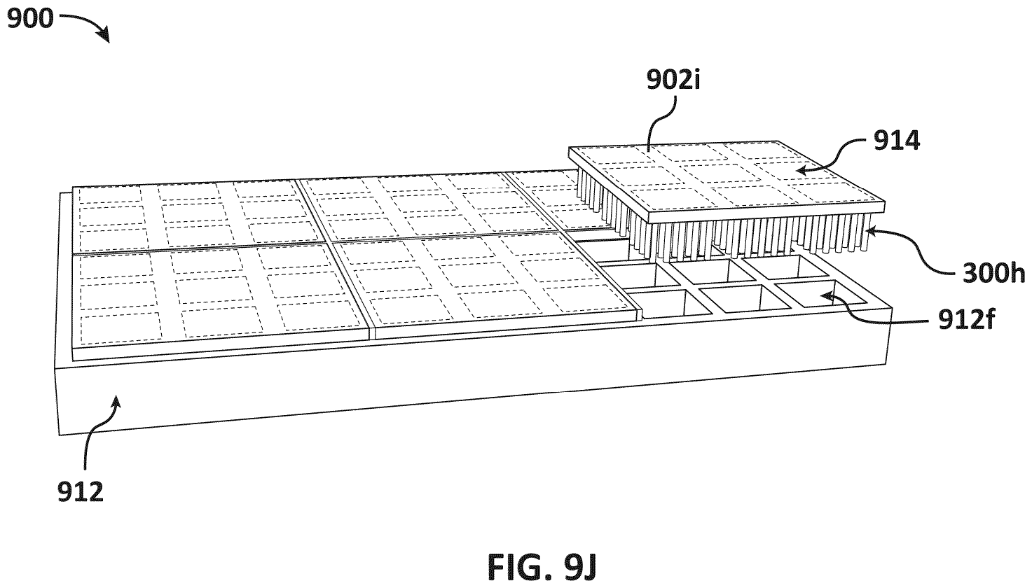

FIG. 9A shows an embodiment where multiple heaters, such as heaters 902a and 902b, and multiple corresponding heat transfer geometries, such as heat transfer geometry 300b, are combined together to form integrated heaters and cold plates, according to some embodiments. The combined heaters and heat transfer geometries are assembled into a larger thermal control assembly 900. Thermal control assembly 900 comprises a large cover structure 912 with cavities, such as cavity 912b. FIG. 9A shows heater 902b and corresponding heat transfer geometry 300b before they are fully assembled into the corresponding cavity 912b in the cover structure 912, while heater 902a has been fully assembled into the cover structure 912. The thermal control assembly 900 may also comprise a PCB 920 (which may house a thermal controller) that has contactors 922 to couple with the pins 910 of the integrated heaters and cold plates.

FIG. 9B shows a section through the thermal control assembly 900 of FIG. 9A, according to some embodiments. FIG. 9B shows how a heater, such as heater 902a, integrated with a corresponding heat transfer geometry, such as 300a, is assembled into a cavity in the cover structure 912. The cover structure 912 may be a monolithic element with multiple cavities and fluid flow paths formed into it and with multiple integrated heaters and cold plates assembled into it. FIG. 9A shows a thermal control assembly 900 comprised of four sets of integrated heaters and cold plates assembled into the cover structure 912, but there is no limit to the number or configuration of the heaters and cold plates and the configuration of the thermal control assembly 900.

In some cases, the thermal control assembly 900 may be configured as a cylindrical structure whose diameter is similar to a diameter of a semiconductor wafer, as shown in FIG. 9C. The thermal control assembly may comprise a heater 902c and a cover structure 912. Such a cylindrical thermal control assembly may be appropriate for controlling the temperature of a semiconductor wafer DUT that is undergoing wafer probe testing. The thermal control assembly 900 of FIG. 9C could be used when testing a semiconductor wafer DUT that has been singulated or diced wherein the chips are still attached to the dicing tape, such as a dicing tape attached to a ring frame. A thermal control assembly 900 configured for wafer probe testing may have additional features such as through holes that provide vacuum ports and related grooves to hold a semiconductor wafer in place during testing, or fiducials or other alignment features on the exposed heaters for alignment of the thermal control assembly to a wafer probe card.

FIG. 9D shows a thermal control assembly 900 configured for testing an undiced or diced semiconductor wafer DUT, where the heater has been designed as four separate quadrants, such as heater quadrant 902d, according to some embodiments. There may be a gap-filling material 907, between the four heater quadrants. Although four quadrants are shown in FIG. 9D, any number, shape, and arrangement of heaters 902 may be possible.

FIG. 9E shows a heater 902e with associated integrated heat transfer geometry 300c before it is assembled to the cover structure 912, according to some embodiments. Cover structure 912 has cavities, such as cavity 912c, to accommodate the heat transfer geometries, such as heat transfer geometry 300c, and cooling fluid. While FIGS. 9D and 9E show a thermal control assembly 900 with the heater segmented into four quadrants, the thermal control assembly could be segmented into any number of pieces of any type of shape.

FIG. 9F shows a thermal control assembly 900 on the left comprising heaters 902 that comprise a plurality of different heating zones outlined by dotted lines, according to some embodiments. The heating zones 914 may comprise isolated resistive traces on a heater 902 that can be individually powered to individually control the heating zone temperature, as an example. FIG. 9F on the right side shows a heater 902f rotated such that the integrated heat transfer geometry 300e on the underside of the heater 902f is depicted in the figure. In this case, the integrated heat transfer geometry 300e extends across multiple heating zones 914. The heater 902f can be assembled into a corresponding cavity in the cover structure 912, such as into cavity 912c depicted in FIG. 9E. Examples of the disclosure may include a plurality of individually controllable heating zones 914 on heaters 902f, where multiple heating zones are cooled by a liquid in a cavity of the cover structure 912, such as cavity 912c, that interacts with the heat transfer geometry 300e that extends across those multiple heating zones 914.

Although FIG. 9G shows a thermal control assembly 900 that includes a heater, such as heater 902g, that comprises a plurality of heating zones 914. Examples of the discourse may include a heat transfer geometry, such as heat transfer geometry 300f, that is thermally coupled to the heating zones 914. For example, there may be a single heat transfer geometry 300f for each heating zone 914.

FIG. 9H shows a heater 902g with integrated heat transfer geometry 300f that is thermally coupled to heating zones 914 being assembled into cover structure 912 of the thermal control assembly 900, according to some embodiments. The cover structure 912 comprises an arrangement of cavities, such as cavity 912d, that correspond to the arrangement of the heat transfer geometries 300, such as heat transfer geometry 300f. In this configuration, both the heating and the cooling of a heating zone 914 can be individually and independently controlled.

In some embodiments, the thermal control assembly 900 is configured for testing a panel (e.g., compared to testing a wafer, as shown in FIG. 9E) and is rectangular in shape. FIG. 91 shows a heater 902h with associated integrated heat transfer geometry 300g before it is assembled to the cover structure 912, according to some embodiments. Cover structure 912 has cavities, such as cavity 912e, to accommodate the heat transfer geometries, such as heat transfer geometry 300g, and cooling fluid.

In some examples, the thermal control assembly 900 is configured for testing a panel versus a wafer and is rectangular in shape. FIG. 9J shows a heater 902i with integrated heat transfer geometry 300h that is thermally coupled to heating zones 914 being assembled into cover structure 912 of the thermal control assembly 900, according to some embodiments. Cover structure 912 has an arrangement of cavities, such as cavity 912f, that correspond to the arrangement of the heat transfer geometries 300, such as heat transfer geometry 300h. In this configuration, both the heating and the cooling of a heating zone 914 can be individually and independently controlled.

While FIGS. 91 and 9J show a thermal control assembly 900 configured for testing panels, with the heater segmented into six elements, the thermal control assembly could be segmented into any number of elements of any type of shape.

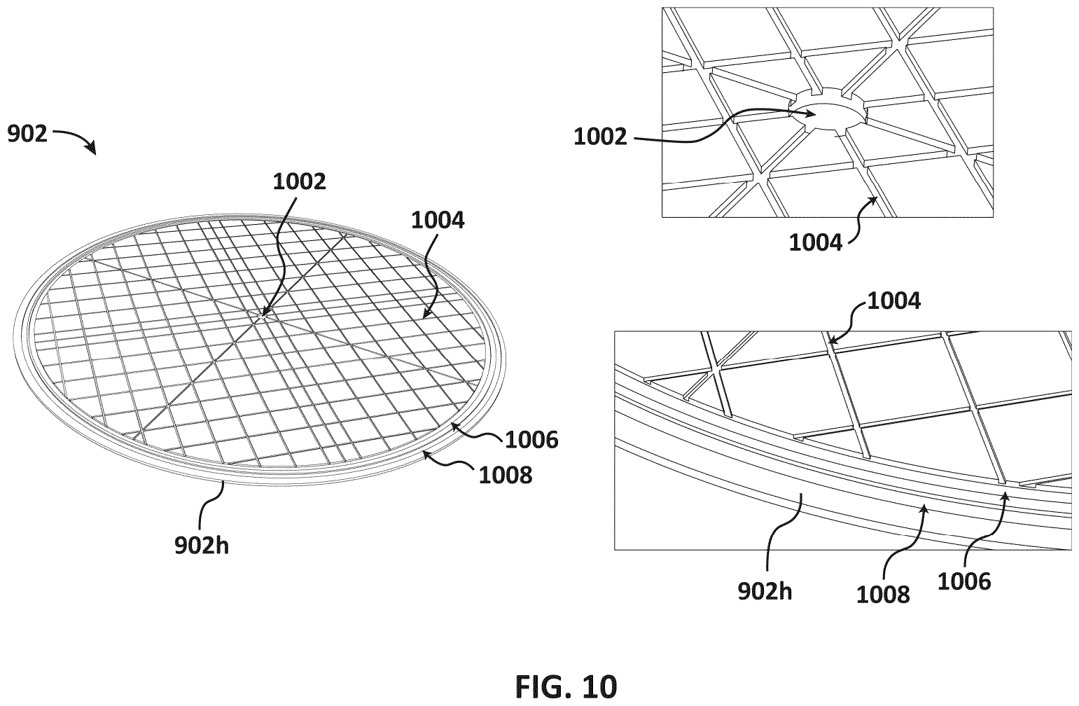

FIG. 10 shows a heater 902 configured to support a liquid thermal interface material (LTIM) or a gas thermal interface material (GTIM), according to some embodiments. The heater 902h has various grooves in its surface, including vacuum groove 1008 which may be used to hold diced or undiced wafer in place for testing when a vacuum is applied to the groove. Heater 902h also includes a plurality of liquid or gas distribution grooves 1004. Also shown is an optional overflow groove 1006. One or more holes may extend through the heater 902 to supply an LTIM or GTIM to the distribution grooves 1004, such as a supply hole 1002. The enlargements in FIG. 10 show the grooves 1004, 1006, and 1008 as well as the supply hole 1002 in greater detail. While FIG. 10 shows an arrangement of these features, any geometry, location, or number of supply holes 1002, vacuum groove 1008, distribution grooves 1004, or overflow groove 1006 may be used. In operation, if an LTIM is being used, the LTIM can be supplied through the supply hole 1002 and can be distributed over the surface of heater 902h via the distribution grooves 1004. Excess LTIM, if there is any, can collect in the overflow groove 1006, if it is present. In operation, if a gas TIM is being used, the GTIM can be supplied through supply hole 1002 and can be distributed over the surface of heater 902h via the LTIM or GTIM distribution grooves 1004. In the case of a GTIM, there may be leaks between the DUT and the surface of heater 902h that allow some GTIM gas to escape from the system. To account for gas leakage within the system there may be a continuous flow of GTIM to the surface of heater 902h with the GTIM flow rate being greater than the gas leakage rate. An LTIM or a GTIM can help reduce the thermal resistance between the heater surface and the DUT by filling very small gaps caused by irregularities in the heater or DUT surface. In some aspects, GTIM gas may be a gas that has a thermal conductivity higher than air, is of reasonable cost, and that has no deleterious effects if released to the atmosphere. Helium is one example GTIM.

After a test cycle is completed, the LTIM can be removed from the heater surface, such as by using a pump to create suction to pull the LTIM from the grooves 1004 and 1006. In the case of GTIM, after a test cycle is completed any excess GTIM can be allowed to escape to the atmosphere. While the grooves 1004 and 1006 and the supply hole are depicted on a wafer-shaped thermal control assembly, the same concept can be applied to any thermal control assembly.

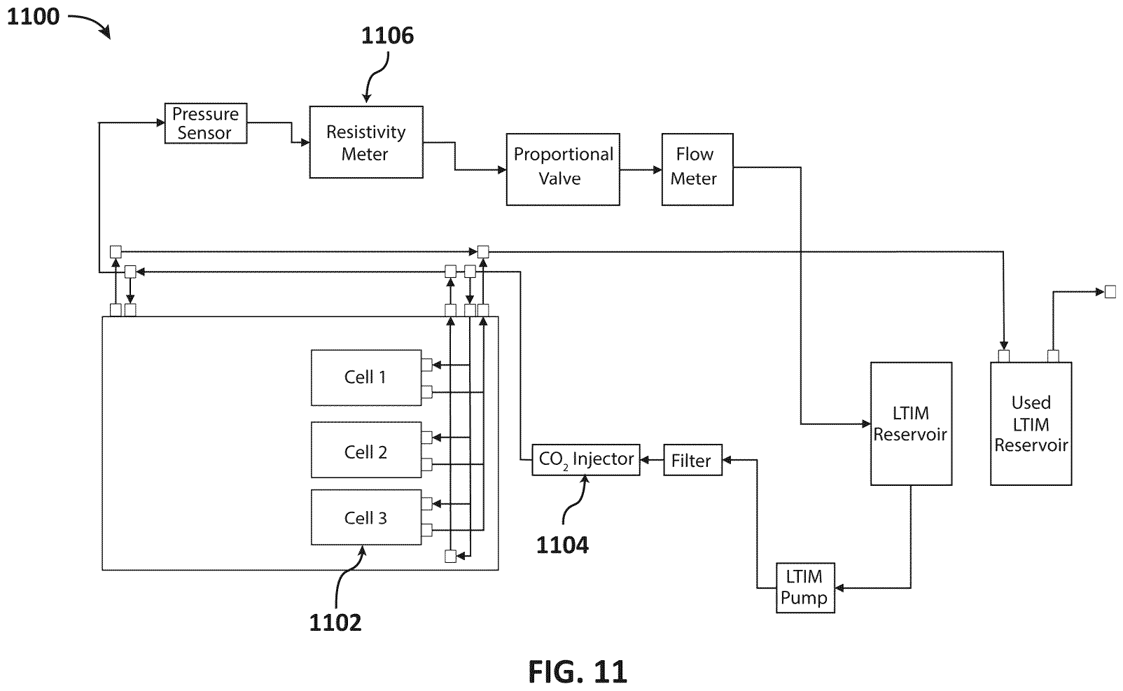

FIG. 11 shows a diagram of an LTIM or GTIM system 1100. The LTIM system 1100 may comprise fluid flow paths, reservoirs, and components to facilitate either gaseous or fluid flow such as a pump and valves, according to some embodiments. The system may also include elements to measure the system performance, such as a pressure sensor or a flow meter, that can provide data that can be used to control the system. The system can provide LTIM or GTIM to one or more thermal control assemblies or to portions of a thermal control assembly, such as the component of FIG. 8A that has five separate heaters and wherein each heater could have its own pattern of grooves and supply hole. The label “cell” 1102 in FIG. 11 is intended to represent a thermal control assembly or a portion of a thermal control assembly. The LTIM or GTIM system 1100 may also include a CO2 injector 1104 and a resistivity meter 1106 that may be used with water or other suitable LTIM. The addition of CO2 to water may change its electrical resistivity. Resistivity is a key factor in determining if a material may build up static charge, which may be unwanted in a test environment. Built up static charge may pose an ESD threat to the semiconductor DUTs, or may attract and collect particles that can deteriorate performance. In the LTIM system 1100, the LTIM resistivity can be monitored by the resistivity meter 1106, and based upon those measurements, the resistivity of the LTIM can be adjusted by the CO2 injector 1104 injecting CO₂ into the LTIM.

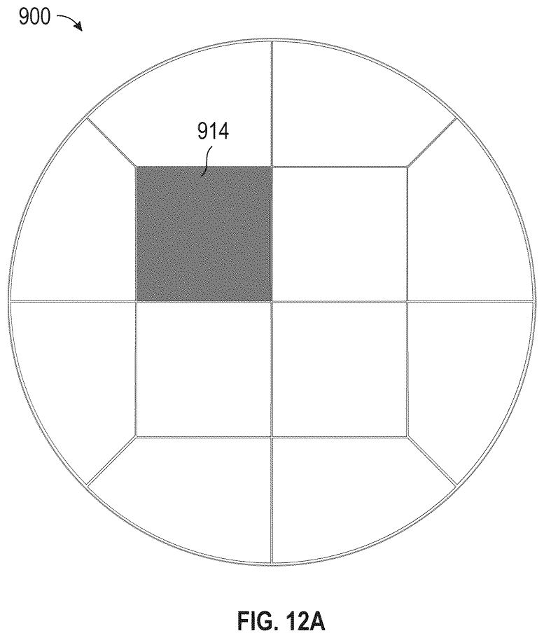

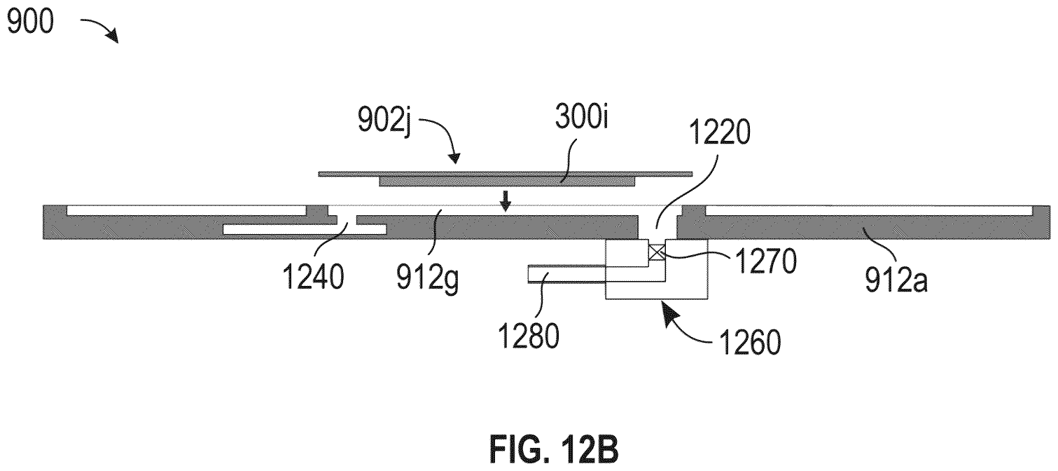

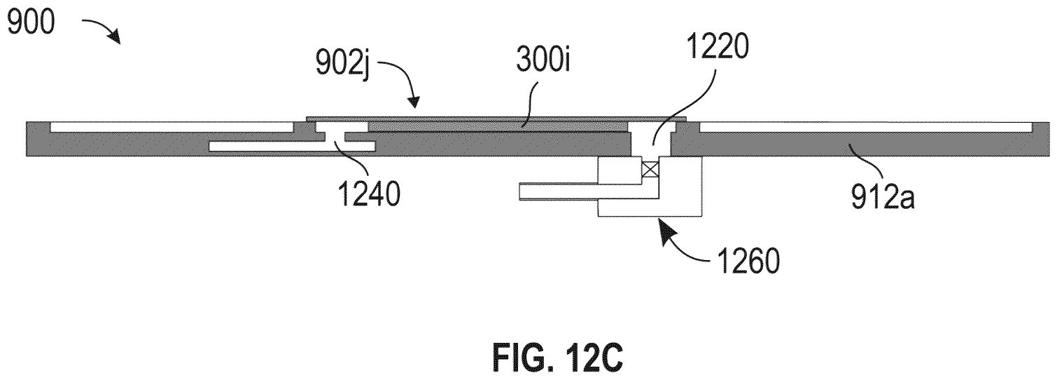

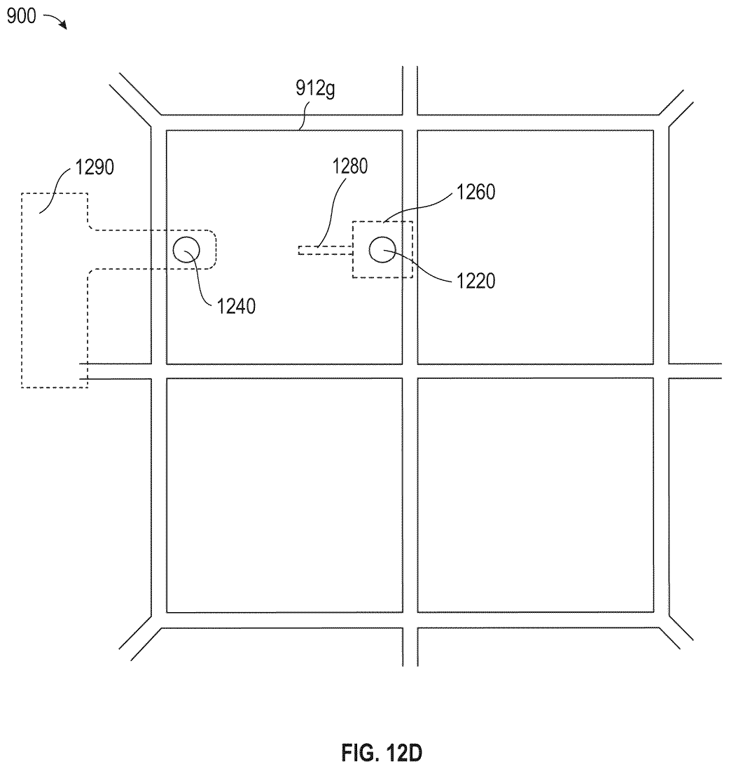

FIG. 12A depicts an example thermal control assembly 900 that is divided into 12 heating zones, such as zone 914. Although FIG. 12A shows a circular thermal control assembly (e.g., for use with wafers), the thermal control assembly of the disclosure may comprise any shape or size.

FIGS. 12B and 12C show side views through a heating zone 914 of a thermal control assembly 900 that includes a cover structure 912a. Heater 902j with an integrated heat transfer geometry 300i fits into a cavity 912g in the cover structure 912a. FIG. 12B shows the heater 902j before it is assembled into the cavity 912g, and FIG. 12C shows the heater 902j after it is assembled into the cavity 912g. There is a fluid inlet 1220 and a fluid outlet 1240 associated with the cavity 912g. A valve assembly 1260 comprises a tube 1280 to transport fluid and a cavity flow control valve 1270. The valve assembly 1260 is shown at the location of and associated with the fluid inlet 1220, but the valve assembly 1260 could alternatively be at the location of and associated with the fluid outlet 1240. The cavity flow control valve 1270 may be used to control the flow of a fluid through the valve assembly 1260 and thereby control the flow of fluid through the cavity 912g. Cavity flow control valve 1270 may be operated as fully open, partially open, or fully closed. With the cavity flow control valve 1270 partially or fully open, a chilled fluid can flow through cavity 912g and interact with the heat transfer geometry 300i to remove heat from the heater 902j and thus lower its temperature.

FIG. 12D shows a top plan view of a portion of the thermal control assembly 900 including cavity 912g, but without the heater 902j installed. There is a cavity fluid inlet 1220 and a cavity fluid outlet 1240 associated with the cavity 912g. The cavity fluid outlet 1240 may be connected to a fluid outlet channel 1290. Fluid flow to the cavity 912g from a tube 1280 may be controlled by valve assembly 1260 that includes the cavity flow control valve 1270.

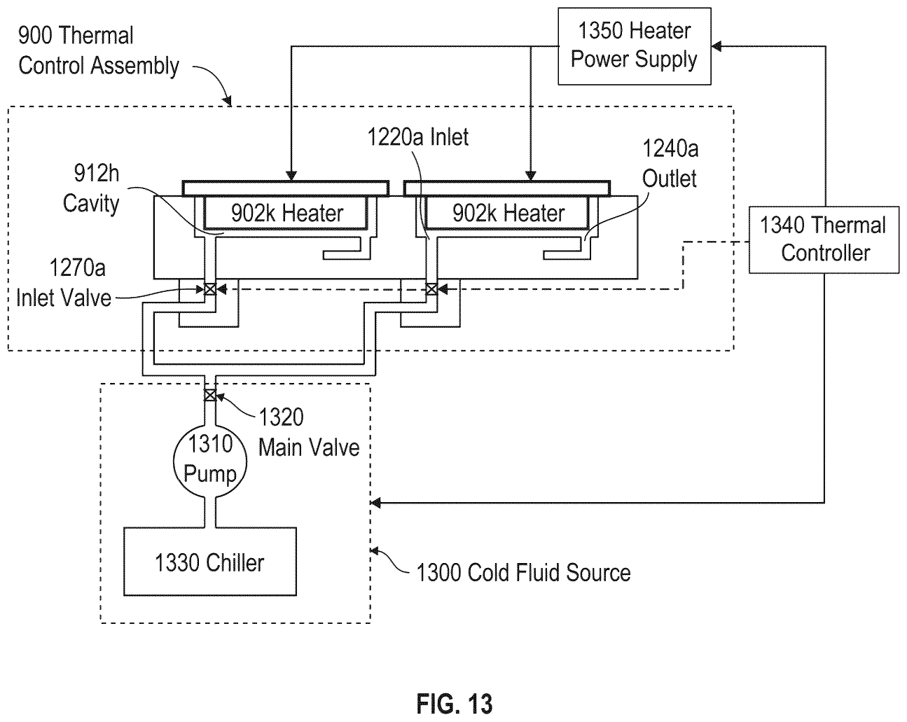

FIG. 13 shows an example temperature control system 1300 for a thermal control assembly 900. A thermal controller 1340 may control the power applied from a heater power supply 1350 to the heaters 902k. Increasing the electrical power to the heaters 902k may raise the temperature of the heaters. Thermal controller 1340 may also control the operation of the cavity flow control valves, such as inlet valve 1270a. Although FIG. 13 shows the cavity flow control valve 1270 associated with the cavity inlet 1220a, as an inlet valve 1270a, the cavity flow control valve 1270 may instead be associated with the cavity outlet 1240a. Included in the temperature control system 1300 is a cold fluid source 1305 that comprises a chiller 1330, a pump 1310, and a main valve 1320. When the cavity inlet valves 1270a are partially or fully opened by the thermal controller 1340 and the cold fluid source 1305 is operating (e.g., the chiller 1330 and pump 1310 are on and the main valve 1320 is at least partially open), then a chilled fluid provided by the cold fluid source 1305 may flow through the cavities 912h to cool the heaters 902k. In some instances the cavity flow control valves 1270 may be turned off and on in rapid succession to provide fine-grained control. This mode of operation, wherein the cavity flow control valves 1270 control the flow of chilled fluid to each cavity allows individual control of the cooling of each cavity and associated heater. In some examples, this mode of operation may also result in a high number of actuations of the cavity flow control valves 1270, which could impact their lifetime. An alternative operating mode may leave one or more of the cavity flow control valves 1270 fully open with chilled fluid flow to the cavities with open cavity flow control valves 1270 provided by the cold fluid source 1305. In other words, the chiller 1330, pump 1310, and main valve 1320 are activated by the thermal controller 1340 to control the temperature and flow rate of a chilled fluid to the thermal control assembly 900. In some aspects, the chilled fluid may be only flowing through cavities with open cavity flow control valves 1270. This mode of operation has the advantage of fewer valve activations. The main valve 1320 may be more robust than cavity flow control valves 1270 and also may be in a more accessible location for easier maintenance. While two heaters 902k are shown in FIG. 13, examples of the disclosure may include any number of heaters in any configuration.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A thermal control system for controlling a temperature of one or more zones of a device under test (DUT), the thermal control system comprising:
an integrated heater and cold plate comprising:
a heater;
a base; and
a heat transfer geometry deposited directly on or permanently attached to the base or the heater.

2. The thermal control system of claim 1, wherein the heater directly contacts the heat transfer geometry.

3. The thermal control system of claim 1, wherein the thermal control system excludes air or a thermal interface material (TIM) between the heater and the heat transfer geometry.

4. The thermal control system of claim 1, wherein the heater is joined to the base.

5. The thermal control system of claim 1, wherein the base is a substrate of the heater.

6. The thermal control system of claim 1, wherein the base comprises a ceramic dielectric material.

7. The thermal control system of claim 1, wherein the base comprises one or more metallization layers.

8. The thermal control system of claim 7, wherein the one or more metallization layers comprise:
an adhesion/barrier layer comprising titanium (Ti), chrome (Cr), tungsten (W), tantalum (Ta), titanium nitride (TiN), tantalum nitride (TaN), or a combination thereof; or
a seed layer comprising copper (Cu), aluminum (Al), gold (Au), nickel (Ni), or a combination thereof.

9. The thermal control system of claim 1, wherein the heat transfer geometry and the base are included in a cold plate.

10. The thermal control system of claim 1, wherein the heat transfer geometry is at least partially formed using a physical vapor deposition process, a plating process, an additive manufacturing process, or a combination thereof.

11. The thermal control system of claim 1, wherein the heat transfer geometry comprises one or more rectangular fins, pin fins, or gyroid fins.

12. The thermal control system of claim 1, wherein the heater comprises a plurality of heating zones, wherein the heat transfer geometry is thermally coupled to multiple of the plurality of heating zones.

13. The thermal control system of claim 1, wherein the heater comprises at least one heating zone, wherein the heat transfer geometry is thermally coupled to the at least one heating zone.

14. The thermal control system of claim 1, wherein the heater is attached to the base through brazing, soldering, transient liquid phase bonding, sintering, adhesive bonding, or another permanent bonding process.

15. The thermal control system of claim 1, further comprising:
threaded studs or mechanical support structures affixed to the heater by brazing, soldering, transient liquid phase bonding, sintering, adhesive bonding, or another permanent bonding process.

16. The thermal control system of claim 1, wherein the heater comprises dielectric layers and conductive layers.

17. The thermal control system of claim 16, wherein the dielectric layers comprise aluminum nitride (AlN).

18. The thermal control system of claim 1, wherein the heater comprises a plurality of independently controlled heating zones.

19. The thermal control system of claim 1, wherein the heater is coupled to a thermal controller, wherein the thermal controller controls the heater by controlling an electrical power supplied to the heater.

20. The thermal control system of claim 1, wherein the heater is capable of being independently controlled separately from the cold plate.

21. The thermal control system of claim 1, wherein the heater and the cold plate are controlled by a thermal controller.

22. The thermal control system of claim 1, wherein the heater is controlled by a first thermal controller, and the cold plate is controlled by a second thermal controller.

23. The thermal control system of claim 1, wherein the cold plate comprises a plurality of independently controlled cooling zones.

24. The thermal control system of claim 1, wherein the cold plate is controlled by a thermal controller, wherein the thermal controller controls a coolant fluid flowing through the cold plate.

25. The thermal control system of claim 1, wherein the heater is configured to support a thermal interface material (TIM).

26. The thermal control system of claim 25, wherein the TIM comprises a liquid TIM or a gas TIM.

27. The thermal control system of claim 26, wherein the gas TIM includes helium.
